(19) United States
(12) Patent Application Publication
(10) Pub. No.: US 2025/0185514 A1
(43) Pub. Date: Jun. 5, 2025

(54) ELECTROMAGNETIC WAVE DETECTOR AND ELECTROMAGNETIC WAVE DETECTOR ARRAY

(71) Applicant: Mitsubishi Electric Corporation, Tokyo (JP)

(72) Inventors: Manabu IWAKAWA, Chiyoda-ku, Tokyo (JP); Shimpei OGAWA, Chiyoda-ku, Tokyo (JP); Masaaki SHIMATANI, Chiyoda-ku, Tokyo (JP); Shoichiro FUKUSHIMA, Chiyoda-ku, Tokyo (JP)

(73) Assignee: Mitsubishi Electric Corporation, Tokyo (JP)

(21) Appl. No.: 18/844,059

(22) PCT Filed: Feb. 14, 2023
(86) PCT No.: PCT/JP2023/004894

§ 371 Date: Sep. 5, 2024

(30) Foreign Application Priority Data
Apr. 25, 2022 (JP) 2022-071669

(51) Int. Cl. H10N 15/10

(52) U.S. Cl. CPC H10N 15/15

(57) ABSTRACT

Provided are an electromagnetic wave detector and an electromagnetic wave detector array having high detection sensitivity. An electromagnetic wave detector includes a semiconductor layer having a first surface, a two-dimensional material layer electrically connected to the semiconductor layer, a first electrode portion electrically connected to the two-dimensional material layer without the semiconductor layer therebetween, a second electrode portion electrically connected to the two-dimensional material layer via the semiconductor layer, and a thermoelectric conversion material layer. The thermoelectric conversion material layer is in contact with the two-dimensional material layer.

### TECHNICAL FIELD

The present disclosure relates to an electromagnetic wave detector and an electromagnetic wave detector array.

### BACKGROUND ART

Conventionally, as a material of an electromagnetic wave detection layer used in a next-generation electromagnetic wave detector, there has been known graphene having an extremely high mobility, which is an example of a two-dimensional material layer. An absorptivity of the graphene is as low as 2.3%. Therefore, there has been proposed a method for increasing sensitivity of an electromagnetic wave detector using the graphene. For example, US 2015/0243826 A (PTL 1) has proposed a detector having the following structure in the description. In other words, in the detector of PTL 1 described above, two or more dielectric layers are arranged on an n-type semiconductor layer. A graphene layer is formed on two dielectric layers and a surface portion of the n-type semiconductor layer located between the two dielectric layers. The graphene layer is in a Schottky junction with the n-type semiconductor layer. Source/drain electrodes connected to both ends of the graphene layer are disposed on the dielectric layer. A gate electrode is connected to the n-type semiconductor layer. In a case where a voltage is applied between the gate electrode and the source electrode or the drain electrode, the above Schottky junction enables OFF operation.

### CITATION LIST

### Patent Literature

PTL 1: US 2015/0243826 A

### SUMMARY OF INVENTION

### Technical Problem

However, in a state where the voltage is applied between the gate electrode and the source electrode or the drain electrode, sensitivity of the detector depends on quantum efficiency of the semiconductor layer. Therefore, sufficient amplification of photocarriers cannot be achieved, and it is difficult to increase the sensitivity of the detector.

A main object of the present disclosure is to provide an electromagnetic wave detector and an electromagnetic wave detector array having higher detection sensitivity than that of the above detector.

### Solution to Problem

The electromagnetic wave detector according to the present disclosure includes: a semiconductor layer having a first surface; a two-dimensional material layer electrically connected to the semiconductor layer; a first electrode portion electrically connected to the two-dimensional material layer without the semiconductor layer between the first electrode portion and the two-dimensional material layer; a second electrode portion electrically connected to the two-dimensional material layer via the semiconductor layer; and a thermoelectric conversion material layer. The thermoelectric conversion material layer is in contact with the two-dimensional material layer, or spaced apart from the two-dimensional material layer in a direction orthogonal to the first surface and arranged to change a potential difference between the first electrode portion and the second electrode portion when a potential difference in the thermoelectric conversion material layer changes.

### Advantageous Effects of Invention

According to the present disclosure, it is possible to provide the electromagnetic wave detector and the electromagnetic wave detector array having the higher detection sensitivity than that of the above detector.

### BRIEF DESCRIPTION OF DRAWINGS

FIG. 1 is a plan view for illustrating an electromagnetic wave detector according to a first embodiment.

FIG. 2 is a cross-sectional view taken along line II-II in FIG. 1.

FIG. 3 is a flowchart for illustrating a manufacturing method of the electromagnetic wave detector according to the first embodiment.

FIG. 4 is a cross-sectional view illustrating a first variation of the electromagnetic wave detector according to the first embodiment.

FIG. 5 is a cross-sectional view illustrating a second variation of the electromagnetic wave detector according to the first embodiment.

FIG. 6 is a plan view for illustrating an electromagnetic wave detector according to a second embodiment.

FIG. 7 is a cross-sectional view taken along line VII-VII in FIG. 6.

FIG. 8 is a plan view illustrating a first variation of the electromagnetic wave detector according to the second embodiment.

FIG. 9 is a cross-sectional view taken along line IX-IX in FIG. 8.

FIG. 10 is a plan view illustrating a second variation of the electromagnetic wave detector according to the second embodiment.

FIG. 11 is a cross-sectional view taken along line XI-XI in FIG. 10.

FIG. 12 is a cross-sectional view for illustrating an electromagnetic wave detector according to a third embodiment.

FIG. 13 is a plan view for illustrating an electromagnetic wave detector according to a fourth embodiment.

FIG. 14 is a cross-sectional view taken along line XIV-XIV in FIG. 13.

FIG. 15 is a plan view for illustrating an electromagnetic wave detector according to a fifth embodiment.

FIG. 16 is a cross-sectional view taken along line XVI-XVI in FIG. 15.

FIG. 17 is a plan view illustrating an electromagnetic wave detector according to a sixth embodiment.

FIG. 18 is a cross-sectional view taken along line XVIII-XVIII in FIG. 17.

FIG. 19 is a cross-sectional view taken along line XIX-XIX in FIG. 17.

FIG. 20 is a cross-sectional view for illustrating an electromagnetic wave detector according to an eighth embodiment.

FIG. 21 is a cross-sectional view for illustrating an electromagnetic wave detector according to a ninth embodiment.

FIG. 22 is a plan view for illustrating an electromagnetic wave detector according to a tenth embodiment.

FIG. 23 is a cross-sectional view taken along line XXIII-XXIII in FIG. 22.

FIG. 24 is a cross-sectional view illustrating a first variation of the electromagnetic wave detector according to the tenth embodiment.

FIG. 25 is a cross-sectional view illustrating a second variation of the electromagnetic wave detector according to the tenth embodiment.

FIG. 26 is a plan view illustrating an electromagnetic wave detector according to an eleventh embodiment,

FIG. 27 is a cross-sectional view taken along line segment XXVII-XXVII in FIG. 26.

FIG. 28 is a plan view illustrating the electromagnetic wave detector according to the eleventh embodiment.

FIG. 29 is a cross-sectional view taken along line XXIX-XXIX in FIG. 28.

FIG. 30 is a cross-sectional view for illustrating an electromagnetic wave detector according to a twelfth embodiment.

FIG. 31 is a cross-sectional view illustrating an electromagnetic wave detector according to a thirteenth embodiment.

FIG. 32 is a cross-sectional view illustrating a variation of the electromagnetic wave detector according to the thirteenth embodiment.

FIG. 33 is a cross-sectional view illustrating an electromagnetic wave detector according to a fourteenth embodiment.

FIG. 34 is a cross-sectional view for illustrating a variation of the electromagnetic wave detector according to the fourteenth embodiment,

FIG. 35 is a cross-sectional view illustrating an electromagnetic wave detector according to a fifteenth embodiment.

FIG. 36 is a cross-sectional view for illustrating a first variation of the electromagnetic wave detector according to the fifteenth embodiment.

FIG. 37 is a cross-sectional view illustrating a second variation of the electromagnetic wave detector according to the fifteenth embodiment.

FIG. 38 is a cross-sectional view illustrating a third variation of the electromagnetic wave detector according to the fifteenth embodiment.

FIG. 39 is a cross-sectional view illustrating an electromagnetic wave detector according to a sixteenth embodiment.

FIG. 40 is a cross-sectional view for illustrating a variation of the electromagnetic wave detector according to the sixteenth embodiment.

FIG. 41 is a cross-sectional view for illustrating an electromagnetic wave detector according to a seventeenth embodiment.

FIG. 42 is a cross-sectional view illustrating a variation of the electromagnetic wave detector according to the seventeenth embodiment.

FIG. 43 is a cross-sectional view for illustrating an electromagnetic wave detector according to a nineteenth embodiment.

FIG. 44 is a cross-sectional view for illustrating an electromagnetic wave detector according to a twentieth embodiment.

FIG. 45 is a cross-sectional view for illustrating an electromagnetic wave detector according to a twenty-first embodiment.

FIG. 46 is a cross-sectional view illustrating a variation of the electromagnetic wave detector according to the twenty-first embodiment,

FIG. 47 is a cross-sectional view for illustrating an electromagnetic wave detector according to a twenty-second embodiment.

FIG. 48 is a cross-sectional view for illustrating a variation of the electromagnetic wave detector according to the twenty-second embodiment.

FIG. 49 is a cross-sectional view for illustrating an electromagnetic wave detector according to a twenty-third embodiment.

FIG. 50 is a plan view for illustrating an electromagnetic wave detector array according to a twenty-fourth embodiment.

FIG. 51 is a plan view illustrating a variation of the electromagnetic wave detector array according to the twenty-fourth embodiment.

### DESCRIPTION OF EMBODIMENTS

Hereinafter, embodiments of the present disclosure will be described with reference to the drawings. Note that the same components are denoted by the same reference numerals, and description thereof will not be repeated.

In the embodiments described below, the drawings are schematic and intended to conceptually describe functions or structures. Further, the present disclosure is not limited to the embodiments described below. Unless otherwise specified, a basic configuration of the electromagnetic wave detector is common to all the embodiments. Further, the components denoted by the same reference numerals are the same or equivalent as described above. This is common throughout the entire description.

In the embodiments described below, although the electromagnetic wave detector will be described by using a configuration in a case of detecting visible light or infrared light, the present disclosure is not limited thereto. The embodiments described below are also effective as a detector that detects radio waves such as an X-ray, ultraviolet light, near-infrared light, a terahertz (THz) wave, or a microwave, in addition to the visible light or the infrared light. Note that, in the embodiments of the present disclosure, the light and radio waves are collectively referred to as electromagnetic waves.

Further, in the embodiments of the present disclosure, a term of p-type graphene or n-type graphene may be used as the graphene. In the following embodiments, graphene having more positive holes than graphene in an intrinsic state is referred to as p-type graphene, and graphene having more electrons than graphene in an intrinsic state is referred to as n-type graphene.

Further, in the embodiments of the present disclosure, a term of n-type or p-type may be used for a material of a member in contact with the graphene, which is an example of the two-dimensional material layer. Here, for example, an n-type material indicates a material having an electron-donating property, and a p-type material indicates a material having an electron-withdrawing property. Further, there is also a case where a bias in charge is observed throughout molecules, and materials in which electrons are dominant may be called the n-type, while materials in which the positive boles are dominant may be called the p-type. As these materials, any one of an organic substance and an inorganic substance or a mixture thereof can be used.

Further, a plasmon resonance phenomenon such as a surface plasmon resonance phenomenon, which is an interaction between a metal surface and light, a phenomenon called a pseudo surface plasmon resonance in a sense of a resonance applied to the metal surface in a region other than a visible light region and a near-infrared light region, or a phenomenon called metamaterial or plasmonic metamaterial in a sense of manipulating a specific wavelength with a structure having a dimension less than or equal to a wavelength are not particularly distinguished by names, and are treated equally in terms of effects exerted by the phenomena. Here, these resonances are referred to as surface plasmon resonances, plasmon resonances, or simply resonances.

Further, in the embodiments described below, although the graphene has been described as an example of the material of the two-dimensional material layer, the material constituting the two-dimensional material layer is not limited to the graphene. For example, as the material of the two-dimensional material layer, it is possible to apply materials such as transition metal dichalcogenide (TMD), black phosphorus, silicene (two-dimensional honeycomb structure formed by silicon atoms), and germanene (two-dimensional honeycomb structure formed by germanium atoms). Examples of the transition metal dichalcogenide include transition metal dichalcogenide such as MoS₂, WS₂, and WSe₂.

These materials have a structure similar to that of the graphene, and are materials in which atoms can be arranged in a single layer within a two-dimensional surface. Accordingly, even in a case where these materials are applied to the two-dimensional material layer, it is possible to obtain a similar action and effect to a case where the graphene is applied to the two-dimensional material layer.

### First Embodiment

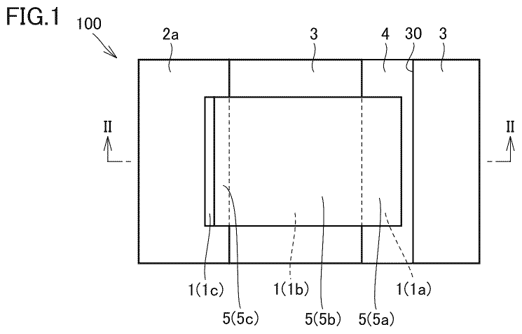

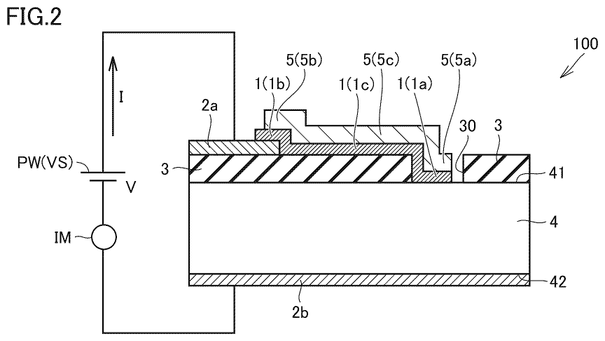

FIG. 1 is a schematic plan view of an electromagnetic wave detector 100 according to the first embodiment. FIG. 2 is a schematic cross-sectional view taken along line II-II in FIG. 1. Electromagnetic wave detector 100 illustrated in FIGS. 1 and 2 mainly includes a two-dimensional material layer 1, a first electrode portion 2a, a second electrode portion 2b, an insulating film 3, a semiconductor layer 4, and a thermoelectric conversion material layer 5.

Semiconductor layer 4 has a first surface 41 and a second surface 42 located on a side opposite to first surface 41. As illustrated in FIGS. 1 and 2, two-dimensional material layer 1, first electrode portion 2a, insulating film 3, and thermoelectric conversion material layer 5 are disposed on first surface 41 of semiconductor layer 4. Second electrode portion 2b is disposed on second surface 42 of semiconductor layer 4.

Semiconductor layer 4 is made of, for example, a semiconductor material such as silicon (Si). Specifically, as semiconductor layer 4, a silicon substrate doped with impurities or the like is used.

Here, semiconductor layer 4 may have a multilayer structure, and a pn junction photodiode, a pin photodiode, a Schottky photodiode, or an avalanche photodiode may be used. Further, a phototransistor may be used as semiconductor layer 4.

Although the silicon substrate has been described as an example of the semiconductor material constituting semiconductor layer 4 as described above, other materials may be used as a material constituting semiconductor layer 4. For example, as the material constituting semiconductor layer 4, a material such as a compound semiconductor, for example, germanium (Ge), or a group III—V or a group II-V semiconductor; a substrate containing mercury cadmium tellurium (HgCdTe), indium antimony (InSb), lead selenium (PbSe), lead sulfur (PbS), cadmium sulfur (CdS), gallium nitride (GaN), silicon carbide (SIC), gallium phosphide (GaP), indium gallium arsenide (InGaAs), indium arsenide (InAs), a quantum well or a quantum dot; or a Type II superlattice may be used alone, or in combination with each other.

In electromagnetic wave detector 100 according to the present embodiment, semiconductor layer 4 and semiconductor layer 4 are preferably doped with the impurities to make electric resistivity of semiconductor layer 4 and semiconductor layer 4 less than or equal to 100 Ωcm. By doping semiconductor layer 4 and semiconductor layer 4 with a high concentration, moving speeds (reading speeds) of carriers in semiconductor layer 4 and semiconductor layer 4 become faster. As a result, a response speed of electromagnetic wave detector 100 is accelerated.

Further, a thickness T1 of semiconductor layer 4 is preferably less than or equal to 10 μm. By reducing thickness T1 of semiconductor layer 4, the carriers are less deactivated.

Insulating film 3 is disposed on first surface 41 of semiconductor layer 4. Insulating film 3 has a lower surface in contact with first surface 41 of semiconductor layer 4 and an upper surface located on a side opposite to the lower surface. An opening 30 through which a part of first surface 41 of semiconductor layer 4 is exposed is formed in insulating film 3. Opening 30 extends from the upper surface to the lower surface of insulating film 3. At least a part of the upper surface of insulating film 3 is in contact with a lower surface of two-dimensional material layer 1. In other words, insulating film 3 is disposed on a lower portion of two-dimensional material layer 1.

As insulating film 3, for example, an insulating film made from silicon oxide (SiO₂) can be used. Note that a material constituting insulating film 3 is not limited to the silicon oxide described above, and other insulating materials may be used. For example, tetraethyl orthosilicate, silicon nitride, hafnium oxide, aluminum oxide, nickel oxide, boron nitride, siloxane-based polymer materials, or the like may be used as the material constituting insulating film 3. For example, since the boron nitride has an atomic arrangement similar to that of the graphene, the boron nitride does not adversely affect charge mobility even when the boron nitride is in contact with two-dimensional material layer 1 made of the graphene. Therefore, the boron nitride is suitable as the material constituting insulating film 3 from a viewpoint of suppressing inhibition of performance of two-dimensional material layer 1 such as electron mobility due to insulating film 3.

Further, a thickness T2 of insulating film 3, that is, a distance between the lower surface and the upper surface of insulating film 3 is not particularly limited as long as first electrode portion 2a is insulated from semiconductor layer 4 and no tunnel current is generated. Further, insulating film 3 may not be disposed on the lower portion of two-dimensional material layer 1.

First electrode portion 2a is disposed on the upper surface of insulating film 3. First electrode portion 2a is disposed at a position away from opening 30 of insulating film 3. First electrode portion 2a has a lower surface in contact with the upper surface of insulating film 3, an upper surface located on a side opposite to the lower surface, and a side surface extending in a direction crossing the upper surface. Second electrode portion 2b is disposed on second surface 42 of semiconductor layer 4. Materials constituting first electrode portion 2a and second electrode portion 2b may be any material having conductivity, and includes, for example, at least one selected from the group consisting of gold (Au), silver (Ag), copper (Cu), aluminum (Al), nickel (Ni), chromium (Cr), and palladium (Pd). Further, an adhesion layer without being illustrated may be formed between first electrode portion 2a and insulating film 3 or between second electrode portion 2b and semiconductor layer 4. The adhesion layer enhances adhesion between first electrode portion 2a and insulating film 3 or adhesion between second electrode portion 2b and semiconductor layer 4. A material constituting the adhesion layer is not particularly limited, but may contain, for example, at least one of chromium (Cr) and titanium (Ti).

As illustrated in FIG. 2, first electrode portion 2a is formed on, for example, the lower portion of two-dimensional material layer 1. Note that first electrode portion 2a may be formed on an upper portion of two-dimensional material layer 1. As illustrated in FIG. 2, second electrode portion 2b is arranged on, for example, the entire second surface 42 of semiconductor layer 4. Note that second electrode portion 2b may be in contact with at least a part of semiconductor layer 4. For example, second electrode portion 2b may be arranged to be in contact with a part of first surface 41, second surface 42, and the side surface extending in the direction crossing first surface 41 of semiconductor layer 4. Such electromagnetic wave detector 100 can detect an electromagnetic wave incident from second surface 42 side. Note that, as illustrated in FIG. 2, electromagnetic wave detector 100 in which second electrode portion 2b is arranged on the entire second surface 42 is suitable in a case where the electromagnetic wave to be detected is incident only from first surface 41 side. In electromagnetic wave detector 100 illustrated in FIG. 2, since the electromagnetic wave incident from first surface 41 side and transmitted through thermoelectric conversion material layer 5 and semiconductor layer 4 is reflected by second electrode portion 2b and reaches thermoelectric conversion material layer 5 again, absorptivity of the electromagnetic wave in thermoelectric conversion material layer 5 is increased.

As illustrated in FIG. 2, a power supply circuit for applying a bias voltage V is electrically connected between first electrode portion 2a and second electrode portion 2b. The above power supply circuit is a circuit for applying a voltage V to two-dimensional material layer 1, and includes a voltage source PW. Voltage source PW is electrically connected to first electrode portion 2a and second electrode portion 2b. Voltage source PW is configured to apply a voltage V1 between first electrode portion 2a and second electrode portion 2b. Accordingly, a current II flows between first electrode portion 2a and second electrode portion 2b. An ammeter without being illustrated for detecting current I in two-dimensional material layer 1 is connected to the above power supply circuit.

Two-dimensional material layer 1 is disposed on first electrode portion 2a, insulating film 3, and semiconductor layer 4. Two-dimensional material layer 1 extends from an inner portion of opening 30 of insulating film 3 to first electrode portion 2a. A part of two-dimensional material layer 1 is disposed on first electrode portion 2a and in contact with first electrode portion 2a. Another part of two-dimensional material layer 1 is disposed in the inner portion of opening 30 of insulating film 3 and in contact with semiconductor layer 4. Two-dimensional material layer 1 is disposed on a lower portion of thermoelectric conversion material layer 5 and in contact with thermoelectric conversion material layer 5. Two-dimensional material layer 1 is disposed between each of first electrode portion 2a, insulating film 3, and semiconductor layer 4, and thermoelectric conversion material layer 5.

Two-dimensional material layer 1 includes a first portion 1a electrically connected to semiconductor layer 4, a second portion 1b electrically connected to first electrode portion 2a, and a third portion 1c electrically connecting first portion 1a and second portion 1b.

First portion 1a is disposed on first surface 41 of semiconductor layer 4 in opening 30 of insulating film 3. First portion 1a is disposed on the lower portion of thermoelectric conversion material layer S. First portion 1a is disposed between semiconductor layer 4 and thermoelectric conversion material layer 5, and in contact with each of semiconductor layer 4 and thermoelectric conversion material layer 5. Preferably, first portion 1a is in the Schottky junction with semiconductor layer 4.

As illustrated in FIG. 1, two-dimensional material layer 1 has, for example, a longitudinal direction and a lateral direction in plan view. First portion 1a of two-dimensional material layer 1 has one end portion in the longitudinal direction of two-dimensional material layer 1, and second portion 1b of two-dimensional material layer 1 has another end portion in the longitudinal direction of two-dimensional material layer 1. Note that, in the electromagnetic wave detector according to the present embodiment, positions of the end portions of two-dimensional material layer 1 in plan view are not particularly limited. First portion 1a may not have the end portion of two-dimensional material layer 1. Two-dimensional material layer 1 may have a fourth portion located on a side opposite to third portion 1c in first portion ta and connected to first portion 1a, and the fourth portion may have an end portion of two-dimensional material layer 1.

Second portion 1b is disposed on the upper surface of insulating film 3. A part of second portion 1b is disposed on the upper surface of first electrode portion 2a. At least a part of second portion 1b is disposed on the lower portion of thermoelectric conversion material layer 5. Second portion 1b is disposed between first electrode portion 2a and thermoelectric conversion material layer 5, and in contact with each of first electrode portion 2a and thermoelectric conversion material layer 5.

Third portion 1c is disposed on the upper surface of insulating film 3 and an inner peripheral surface of opening 30 of insulating film 3. Third portion 1c is disposed between insulating film 3 and thermoelectric conversion material layer 5, and in contact with each of insulating film 3 and thermoelectric conversion material layer 5. In other words, insulating film 3 separates third portion 1c of two-dimensional material layer 1 from semiconductor layer 4.

A thickness of each of first portion 1a, second portion 1b, and third portion 1c of two-dimensional material layer 1 is, for example, equal to each other. On the upper surface of two-dimensional material layer 1, irregularities resulting from first portion 1a, second portion 1b, and third portion 1c are formed. A distance between an upper surface of first portion 1a and first surface 41 of semiconductor layer 4 is shorter than a distance between an upper surface of second portion 1b and first surface 41 of semiconductor layer 4.

Two-dimensional material layer 1 includes a region in contact with thermoelectric conversion material layer 5 and a region in contact with semiconductor layer 4. Thermoelectric conversion material layer 5 is arranged to generate an electric field in a direction perpendicular to an extending direction of two-dimensional material layer 1 in at least one of the region of two-dimensional material layer 1 in contact with thermoelectric conversion material layer 5 and the region of two-dimensional material 20 layer 1 in contact with semiconductor layer 4.

Note that two-dimensional material layer 1 in FIG. 2 extends from first electrode portion 2a side (a left side in FIG. 2) to a side opposite to first electrode portion 2a (a right side in FIG. 2) with respect to a center of opening 30 of insulating film 3, but is not limited thereto. In FIG. 2, an end portion (a right end) of two-dimensional material layer 1 located on a side opposite to first electrode portion 2a may be disposed on a left side with respect to the center of opening 30 of insulating film 3. Further, two-dimensional material layer 1 in FIG. 2 is disposed to expose a part of first surface 41 of semiconductor layer 4 at opening 30 of insulating film 3, but is not limited thereto. Two-dimensional material layer 1 may be disposed to cover the entire first surface 41 of semiconductor layer 4 at opening 30 of insulating film 3. The end portion (the right end) of two-dimensional material layer 1 located on the side opposite to first electrode portion 2a may be disposed on insulating film 3 located on a side opposite to first electrode portion 2a with respect to opening 30.

As two-dimensional material layer 1, for example, a single-layer graphene can be used. The single-layer graphene is a monatomic layer of a two-dimensional carbon crystal. Further, the single-layer graphene has carbon atoms in each chain disposed in a hexagonal shape. Further, two-dimensional material layer 1 may be configured as multilayer graphene in which the single-layer graphene is laminated in two or more layers. Further, non-doped graphene or graphene doped with p-type or n-type impurities may be used as two-dimensional material layer 1. A two-dimensional surface of two-dimensional material layer 1 is along the upper surface of two-dimensional material layer 1. An absolute value of an angle formed by the two-dimensional surface of two-dimensional material layer 1 with respect to the upper surface of two-dimensional material layer 1 is greater than or equal to 0°) and less than or equal to 10°. The two-dimensional surface of two-dimensional material layer 1 is, for example, parallel to the upper surface of two-dimensional material layer 1.

In a case where the multilayer graphene is used for two-dimensional material layer 1, photoelectric conversion efficiency of two-dimensional material layer 1 increases, and sensitivity of electromagnetic wave detector 100 becomes high. In the multilayer graphene used as two-dimensional material layer 1, orientations of lattice vectors of hexagonal lattices in any two-layer graphene may not coincide or may coincide. For example, by laminating two or more layers of graphene, a band gap is formed in two-dimensional material layer 1. As a result, it is possible to provide a wavelength selection effect of the electromagnetic wave to be photoelectrically converted. Note that if the number of layers of the multilayer graphene constituting two-dimensional material layer 1 increases, mobility of the carriers in a channel region decreases. Meanwhile, in this case, two-dimensional material layer 1 is less likely to be affected by carrier scattering from a base structure such as a substrate, and as a result, a noise level decreases. Therefore, with electromagnetic wave detector 100 using the multilayer graphene as two-dimensional material layer 1, light absorption is enhanced, and detection sensitivity for the electromagnetic wave can be increased.

Further, in a case where two-dimensional material layer 1 is in contact with first electrode portion 2a, the carriers are doped from first electrode portion 2a to two-dimensional material layer 1. For example, in a case where gold (Au) is used as a material of first electrode portion 2a, the positive holes are doped in two-dimensional material layer 1 near first electrode portion 2a due to a difference in work function between two-dimensional material layer 1 and Au. If electromagnetic wave detector 100 is driven in an electron conduction manner in this state, mobility of electrons flowing in the channel region of two-dimensional material layer 1 decreases, and a contact resistance between two-dimensional material layer 1 and first electrode portion 2a increases due to influence of the positive holes doped in two-dimensional material layer 1 from first electrode portion 2a. Due to the increase in the contact resistance, the mobility of the electrons (the carriers) due to an electric field effect in electromagnetic wave detector 100 decreases, and performance of electromagnetic wave detector 100 can be deteriorated. In particular, in a case where the single-layer graphene is used as two-dimensional material layer 1, doping amounts of the carriers injected from first electrode portion 2a is large. Therefore, the decrease in the mobility of the electron described above in electromagnetic wave detector 100 is particularly remarkable in a case where the single-layer graphene is used as two-dimensional material layer 1. Accordingly, in a case where the entire two-dimensional material layer 1 is formed by the single-layer graphene, the performance of electromagnetic wave detector 100 may be deteriorated.

Therefore, second portion 1b of two-dimensional material layer 1 that is easily doped with the carriers from first electrode portion 2a may contain the multilayer graphene. The multilayer graphene has less carrier doping from first electrode portion 2a than the single-layer graphene. Therefore, the increase in the contact resistance between two-dimensional material layer 1 and first electrode portion 2a can be suppressed. As a result, it is possible to suppress the decrease in the mobility of the electrons described above in electromagnetic wave detector 100, and the performance of electromagnetic wave detector 100 is improved.

Further, as two-dimensional material layer 1, nanoribbon-shaped graphene (hereinafter, also referred to as graphene nanoribbon) can also be used. In this case, as two-dimensional material layer 1, for example, it is possible to use one of single graphene nanoribbon, a composite obtained by laminating a plurality of the graphene nanoribbons, or a structure in which the graphene nanoribbons are periodically arranged on a plane. For example, in a case where the structure in which the graphene nanoribbons are periodically disposed is used as two-dimensional material layer 1, the plasmon resonance can be generated in the graphene nanoribbons. As a result, the sensitivity of electromagnetic wave detector 100 can be improved. Here, the structure in which the graphene nanoribbons are periodically arranged may also be referred to as graphene metamaterial. Accordingly, the effects described above can also be obtained also in electromagnetic wave detector 100 using the graphene metamaterial as two-dimensional material layer 1.

Thermoelectric conversion material layer 5 is arranged to generate or change a temperature difference and the potential difference inside thermoelectric conversion material layer 5 when irradiated with the electromagnetic wave to be detected by electromagnetic wave detector 100. From a different viewpoint, thermoelectric conversion material layer 5 is arranged to absorb the electromagnetic wave to be detected by electromagnetic wave detector 100 to generate or change the temperature difference inside thermoelectric conversion material layer S. Moreover, thermoelectric conversion material layer 5 is arranged to exhibit an effect that when the temperature difference is generated or changed in thermoelectric conversion material layer 5, the potential difference is generated or changed due to the temperature difference (hereinafter, described as a thermoelectric power generation effect).

The temperature difference is generated between a surface irradiated with the electromagnetic wave in thermoelectric conversion material layer 5 and a surface located on a side opposite to the surface irradiated with the electromagnetic wave in a traveling direction of the electromagnetic wave. For example, in a case where the upper surface of thermoelectric conversion material layer 5 is irradiated with the electromagnetic wave, the above temperature difference is generated between the upper surface and the lower surface of thermoelectric conversion material layer S. In this case, an arrangement direction between the regions where the temperature difference is generated in thermoelectric conversion material layer 5 (hereinafter, described as a temperature difference direction) and an arrangement direction between the regions where the potential difference is generated (hereinafter, described as a potential difference direction) cross the two-dimensional surface of two-dimensional material layer 1.

Preferably, thermoelectric conversion material layer 5 is arranged to make a direction of the above potential difference orthogonal to the two-dimensional surface of two-dimensional material layer 1.

Preferably, thermoelectric conversion material layer 5 is arranged to make the direction of the above potential difference orthogonal to the two-dimensional surface of two-dimensional material layer 1 at at least one of an interface between two-dimensional material layer 1 and thermoelectric conversion material layer 5 and a junction interface between two-dimensional material layer 1 and semiconductor layer 4. In this way, it is possible to maximize a rate of change in an electrical resistance of two-dimensional material layer 1 due to an optical gate effect.

Since the electromagnetic wave simply acts as a heat source in the thermoelectric power generation effect, thermoelectric conversion material layer 5 basically exhibits the thermoelectric power generation effect without depending on a wavelength of the electromagnetic wave. Therefore, thermoelectric conversion material layer 5 is sensitive to a broadband electromagnetic wave and sensitive to the wavelength of the electromagnetic wave to be detected by electromagnetic wave detector 100.

Moreover, thermoelectric conversion material layer 5 illustrated in FIG. 2 is arranged to change an electric resistance value of two-dimensional material layer 1 when the above potential difference is generated inside thermoelectric conversion material layer 5. From a different viewpoint, thermoelectric conversion material layer is arranged to exhibit an effect of achieving a state where a gate voltage is applied in a pseudo manner to two-dimensional material layer 1 due to the potential difference generated in thermoelectric conversion material layer 5 (hereinafter, referred to as optical gate effect).

As illustrated in FIG. 2, thermoelectric conversion material layer 5 is in contact with two-dimensional material layer 1. Thermoelectric conversion material layer 5 is disposed on the upper portion of two-dimensional material layer 1. In other words, thermoelectric conversion material layer 5 is disposed on a side opposite to semiconductor layer 4 with respect to two-dimensional material layer 1.

Thermoelectric conversion material layer 5 is disposed on each of first portion 1a, second portion 1b, and third portion 1c of two-dimensional material layer 1, and in contact with each of first portion 1a, second portion 1b, and third portion 1c of two-dimensional material layer 1.

Specifically, thermoelectric conversion material layer 5 includes a fourth portion 5a disposed on first portion 1a of two-dimensional material layer 1 and in contact with first portion 1a, a fifth portion 5b disposed on second portion 1b of two-dimensional material layer 1 and in contact with second portion 1b, and a sixth portion 5c disposed on third portion 1c of two-dimensional material layer 1 and in contact with third portion 1c.

As illustrated in FIG. 2, thermoelectric conversion material layer 5 is not in contact with each of first electrode portion 2a, insulating film 3, and semiconductor layer 4, for example.

As illustrated in FIG. 2, thicknesses of fourth portion 5a, fifth portion 5b, and sixth portion Se of thermoelectric conversion material layer 5 are, for example, equal to each other. On the upper surface of thermoelectric conversion material layer 5, irregularities resulting from the irregularities on the upper surface of two-dimensional material layer 1 are formed.

Note that the thicknesses of fourth portion 5a, fifth portion 5b, and sixth portion 5c of thermoelectric conversion material layer 5 may be different from each other. The upper surface of thermoelectric conversion material layer 5 may be flat, for example.

Preferably, a thickness of thermoelectric conversion material layer 5 is set to make thermoelectric conversion material layer 5 exhibit sufficient thermoelectric power generation effect and optical gate effect. The thickness of thermoelectric conversion material layer 5 is, for example, greater than or equal to 0.1 μm and less than or equal to 10 μm.

Preferably, a temperature change speed of thermoelectric conversion material layer 5 is designed to be as quick as possible. For example, it is desirable that the surface of thermoelectric conversion material layer 5 irradiated with the electromagnetic wave has a high flatness.

The material constituting thermoelectric conversion material layer 5 includes at least one selected from the group consisting of a bismuth-tellurium-based compound, a telluride-based compound, an antimony-tellurium compound, a zinc-antimony compound, a silicon-germanium compound, a selenide-based compound, a silicide-based compound, an oxide material, a sulfide-based material, a Heusler material, a skutterudite-based material, and a chalcogenide-based material. The bismuth-tellurium-based compound is, for example, bismuth telluride (Bi₂Te₃). The telluride-based compound is, for example, magnesium telluride (MgTe), germanium telluride (GeTe), or lead telluride (PbTe). The antimony-tellurium compound is, for example, diantimony tritelluride (SbTes). The zinc-antimony compound is, for example, ZnSb, Zn₃Sb₂, or Zn₄Sb₃. The silicon-germanium compound is, for example, silicon germanium (SiGe). The selenide-based compound is, for example, bismuth selenide (Bi₂Se₃), copper selenide (Cu₂Se), or tin selenide (SnSe). The silicide-based compound is, for example, magnesium silicide (Mg₂Si), manganese silicide (MnSi_{1.73}), chromium silicide (CrSi₂), or iron silicide (β-FeSi₂). The material constituting thermoelectric conversion material layer 5 is not limited to the above thermoelectric conversion material, but may be any thermoelectric conversion material that exhibits the thermoelectric power generation effect. Further, thermoelectric conversion material layer 5 may be a mixture of different thermoelectric conversion materials, or may be a multilayer body in which a plurality of layers made of the thermoelectric conversion materials different from each other are laminated.

Thermoelectric conversion material layer 5 may have, for example, a p-type or n-type polarity. In this case, the polarity of thermoelectric conversion material layer 5 can be controlled by, for example, an impurity material added to the above material and a concentration of the impurity material.

An electrical conductivity of thermoelectric conversion material layer 5 is not particularly limited. The electrical conductivity of thermoelectric conversion material layer 5 can be controlled by, for example, concentrations of the above impurities and a particle diameter of the material constituting thermoelectric conversion material layer 5.

### <Manufacturing Method of Electromagnetic Wave Detector 100>

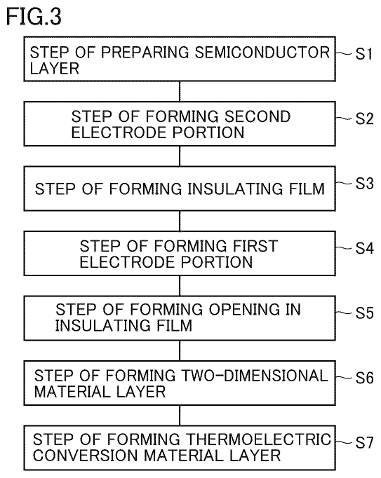

FIG. 3 is a flowchart for illustrating a manufacturing method of electromagnetic wave detector 100 according to the first embodiment. The manufacturing method of electromagnetic wave detector 100 illustrated in FIGS. 1 and 2 will be described with reference to FIG. 3.

First, a step (S1) of preparing semiconductor layer 4 is performed. In this step (S1), for example, semiconductor layer 4 is prepared as a flat substrate made from Si or the like.

Next, a step (S2) of forming the second electrode portion is performed. In this step (S2), second electrode portion 2b is formed on second surface 42 of semiconductor layer 4 (see FIG. 2). Specifically, first, a protective film covering first surface 41 of semiconductor layer 4 is formed. The protective film is, for example, a resist. Next, second electrode portion 2b is formed on second surface 42 of semiconductor layer 4. A material constituting second electrode portion 2b includes, for example, at least one selected from the group consisting of gold (Au), silver (Ag), copper (Cu), aluminum (Al), nickel (Ni), and chromium (Cr).

Note that, in this step (S2), before second electrode portion 2b is formed, an adhesion layer for improving the adhesion between semiconductor layer 4 and second electrode portion 2b may be formed on second surface 42 of semiconductor layer 4. The material constituting the adhesion layer contains, for example, at least one of copper (Cr) and titanium (Ti). Note that this step (S2) may be performed after steps (S3 to S7) to be described later as long as first surface 41 of semiconductor layer 4 is protected.

Next, a step (S3) of forming the insulating film is performed. In this step (S3), insulating film 3 is formed on first surface 41 of semiconductor layer 4. A method for forming insulating film 3 is not particularly limited, and can be arbitrarily selected from, for example, a thermal oxidation method, a chemical vapor deposition (CVD) method, and a sputtering method. In a case where the material Si constituting semiconductor layer 4 is included, insulating film 3 may be, for example, SiO₂ formed by partially thermally oxidizing first surface 41 of semiconductor layer 4.

Next, a step (S4) of forming the first electrode portion is performed. In this step (S4), first electrode portion 2a is formed on insulating film 3.

The method for forming first electrode portion 2a is not particularly limited, but for example, the following lift-off method can be adopted. First, a resist mask is formed on the upper surface of insulating film 3 by photolithography, EB drawing, or the like. In the resist mask, an opening is formed in a region where first electrode portion 2a is to be formed. Second, a conductive film to be first electrode portion 2a is formed on an upper surface of the resist mask by using a vapor deposition method, a sputtering method, or the like. The conductive film is formed to extend from an inner portion of the opening of the resist mask to an upper surface of the resist mask. Third, the resist mask is removed together with a part of the conductive film disposed on the upper surface of the resist mask. Accordingly, another part of the conductive film disposed in the opening of the resist mask remains on the surface of insulating film 3 to become first electrode portion 2a. First electrode portion 2a may be formed by, for example, a method. First, the conductive film to be first electrode portion 2a is formed on the upper surface of insulating film 3. Second, the resist mask is formed on the conductive film by a photolithography method. The resist mask is formed to cover the region where first electrode portion 2a is to be formed, and is not formed in a region other than the region where first electrode portion 2a is to be formed. Third, the conductive film is partially removed by using the resist mask as a mask through at least one of wet etching and dry etching. As a result, a part of the conductive film remaining under the resist mask becomes first electrode portion 2a. Fourth, the resist mask is removed.

Note that before first electrode portion 2a is formed, an adhesion layer for improving adhesion between semiconductor layer 4 and first electrode portion 2a may be formed on first surface 41 of semiconductor layer 4.

Next, a step (S5) of forming an opening in the insulating film is performed. In this step (S5), opening 30 (see FIGS. 1 and 2) is formed in insulating film 3. First, the resist mask is formed on the upper surface of insulating film 3 by using the photolithography, the EB drawing, or the like. In the resist mask, an opening is formed in a region where the opening of insulating film 3 is to be formed. Second, insulating film 3 is partially removed by using the resist mask as a mask through at least one of the wet etching and the dry etching, and opening 30 is formed in insulating film 3. Third, the resist mask is removed. Note that this step (S5) may be performed before the above step (S4).

Next, a step (S6) of forming the two-dimensional material layer is performed. In this step (S6), for example, the two-dimensional material layer is formed to cover the entire first surface 41 of semiconductor layer 4 exposed in first electrode portion 2a, insulating film 3, and opening 30 of insulating film 3, and then the two-dimensional material layer is patterned to form two-dimensional material layer 1 illustrated in FIGS. 1 and 2.

A method for forming two-dimensional material layer 1 is not particularly limited. Two-dimensional material layer 1 may be formed on a part of first electrode portion 2a, insulating film 3, and semiconductor layer 4 by, for example, an epitaxial growth method or a screen printing method. Further, two-dimensional material layer 1 may be formed by transferring and pasting a film-like two-dimensional material layer formed on a substrate different from semiconductor layer 4 by the CVD method or the like or a film-like two-dimensional material layer peeled from graphite or the like by mechanical peeling or the like onto a part of first electrode portion 2a, insulating film 3, and semiconductor layer 4. A method for patterning two-dimensional material layer 1 is not particularly limited, but the photolithography, the EB drawing, or the like can be adopted. In a case where the patterning is performed by using the mask, the mask is removed after two-dimensional material layer 1 is formed.

Next, a step (S7) of forming the thermoelectric conversion material layer is performed. In this step (S7), thermoelectric conversion material layer 5 is formed on the upper surface of two-dimensional material layer 1. A method for forming thermoelectric conversion material layer 5 is not particularly limited. For example, in a case where thermoelectric conversion material layer 5 is made of a polymer-based material, thermoelectric conversion material layer 5 can be formed by patterning a polymer film formed by a spin coating method or the like through the photolithography method. Further, thermoelectric conversion material layer 5 can be formed, for example, by patterning a thermoelectric conversion material film formed by at least one of sputtering, vapor deposition, or a metal organic composition (MOD) coating method through the photolithography method. Further, thermoelectric conversion material layer 5 can also be formed by the lift-off method.

Electromagnetic wave detector 100 illustrated in FIGS. 1 and 2 can be manufactured by the above steps (S1 to S7). Note that, in the manufacturing method described above, two-dimensional material layer 1 is formed on first electrode portion 2a, but first electrode portion 2a may be formed on two-dimensional material layer 1 and insulating film 3. In other words, the step (S4) may be performed after the step (S6). However, in a case where first electrode portion 2a is formed on two-dimensional material layer 1 and insulating film 3, care is necessary to avoid process damage to two-dimensional material layer 1 when first electrode portion 2a is formed. For example, it is conceivable to form the protective film for protecting a region other than a region formed by overlapping with first electrode portion 2a in two-dimensional material layer 1, and then form first electrode portion 2a.

### <Operating Principle of Electromagnetic Wave Detector 100>

Next, an operation principle of electromagnetic wave detector 100 according to the present embodiment will be described.

A state where electromagnetic wave detector 100 in a state where the electromagnetic wave can be detected is not irradiated with the electromagnetic wave is referred to as dark state below. In a case where electromagnetic wave detector 100 is connected to the power supply circuit illustrated in FIG. 2, in the dark state, the voltage V is applied between first electrode portion 2a and second electrode portion 2b, Current I flowing through two-dimensional material layer 1 is measured by the above ammeter. In the dark state, current I may or may not flow through two-dimensional material layer 1.

Thermoelectric conversion material layer 5 of electromagnetic wave detector 100 in the dark state is irradiated with the electromagnetic wave. The potential difference is generated in thermoelectric conversion material layer 5 due to the thermoelectric power generation effect, and as a result, the electric resistance value of two-dimensional material layer 1 changes due to the optical gate effect. Current I flowing through two-dimensional material layer 1 changes due to a change in the electric resistance value of two-dimensional material layer 1. The current flowing through two-dimensional material layer 1 due to irradiation of thermoelectric conversion material layer 5 with the electromagnetic wave is also referred to as photocurrent. In a state where thermoelectric conversion material layer 5 is irradiated with the electromagnetic wave, current I increases by the photocurrent as compared with the dark state. By detecting the change in current I, the electromagnetic wave with which electromagnetic wave detector 100 is irradiated can be detected.

Preferably, voltage V is set to be a reverse bias for the Schottky junction between two-dimensional material layer 1 and semiconductor layer 4. For example, in a case where semiconductor layer 4 constituting semiconductor layer 4 is made of a p-type silicon material and two-dimensional material layer 1 is made of an n-type graphene material, two-dimensional material layer 1 is in the Schottky junction with semiconductor layer 4. At this time, by adjusting voltage V to be the reverse bias for the above Schottky junction, the current (a dark current) flowing through two-dimensional material layer 1 in the dark state can become zero. Such electromagnetic wave detector 100 can be turned off. Specifically, when thermoelectric conversion material layer 5 is irradiated with the electromagnetic wave, the potential difference is generated in thermoelectric conversion material layer 5 due to the thermoelectric power generation effect, a Fermi level of two-dimensional material layer 1 is modulated, and an energy barrier between two-dimensional material layer 1 and semiconductor layer 4 is deteriorated. As a result, the current flows through semiconductor layer 4, and current I is detected only when the irradiation is performed with the electromagnetic wave.

### <Operation of Electromagnetic Wave Detector>

Next, a specific operation of the electromagnetic wave detector illustrated in FIGS. 1 and 2 will be described. Here, there will be described a case where semiconductor layer 4 contains the p-type silicon, two-dimensional material layer 1 contains the graphene, and thermoelectric conversion material layer 5 contains the bismuth-tellurium-based compound.

As illustrated in FIG. 2, if a voltage is applied to have the reverse bias for the Schottky junction between two-dimensional material layer 1 and semiconductor layer 4, a depletion layer is formed near the junction interface between two-dimensional material layer 1 and semiconductor layer 4. A range of a detection wavelength of the electromagnetic wave detector is determined according to an absorption wavelength of the bismuth-tellurium-based compound.

If the electromagnetic wave having the detection wavelength is incident on thermoelectric conversion material layer 5, the potential difference is generated in thermoelectric conversion material layer 5 due to the thermoelectric power generation effect. If the potential difference is generated in thermoelectric conversion material layer 5, the electric field changes in two-dimensional material layer 1 due to the optical gate effect. As described above, the graphene constituting two-dimensional material layer 1 has a high mobility, and can obtain a large displacement current in response to a slight change in the electric field. Therefore, the Fermi level of two-dimensional material layer 1 greatly changes due to the thermoelectric power generation effect of thermoelectric conversion material layer 5, and the energy barrier with semiconductor layer 4 is deteriorated. Accordingly, the charge is injected from first electrode portion 2a into two-dimensional material layer 1. Moreover, a photo-injected current charge extracted from semiconductor layer 4 is greatly amplified due to the optical gate effect in two-dimensional material layer 1. Therefore, the detection sensitivity of the electromagnetic wave by electromagnetic wave detector 100 according to the present embodiment can be high exceeding a quantum efficiency of 100%.

### <Variation>

Electromagnetic wave detector 100 can be deformed as follows.

Electromagnetic wave detector 100 may further include a Mott insulator that is in contact with thermoelectric conversion material layer 5 and in which a light-induced phase transition occurs by light irradiation to change physical properties (for example, a temperature).

Electromagnetic wave detector 100 may further include a protective film that covers an exposed surface of each of two-dimensional material layer 1, semiconductor layer 4, first electrode portion 2a, and thermoelectric conversion material layer 5. A material constituting the protective film is not particularly limited, but may be, for example, a material having an electrical insulation property. The material constituting the protective film may include, for example, at least one selected from the group consisting of silicon oxide, silicon nitride, hafnium oxide, aluminum oxide, and boron nitride.

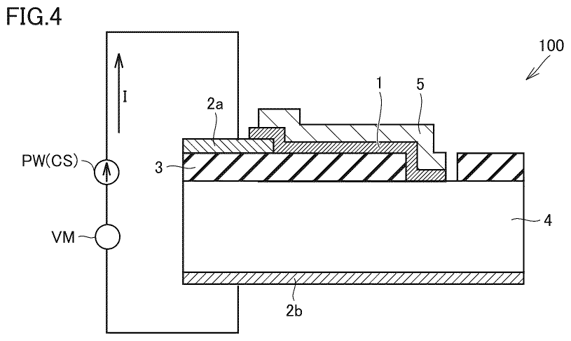

As illustrated in FIG. 4, a power supply circuit for applying a bias current i may be electrically connected between first electrode portion 2a and second electrode portion 2b of electromagnetic wave detector 100 instead of the power supply circuit for applying the bias voltage V. The above power supply circuit is a circuit for applying bias current I to two-dimensional material layer 1, and includes a current source without being illustrated and a voltmeter VM. The current source is configured to apply bias current I between first electrode portion 2a and second electrode portion 2b. The current source is, for example, a constant current source. In electromagnetic wave detector 100 illustrated in FIG. 4, voltmeter VM detects the change in the electric resistance value of two-dimensional material layer 1 caused by the optical gate effect when thermoelectric conversion material layer 5 is irradiated with the electromagnetic wave as a change in a voltage generated between first electrode portion 2a and second electrode portion 2b, to detect the electromagnetic wave.

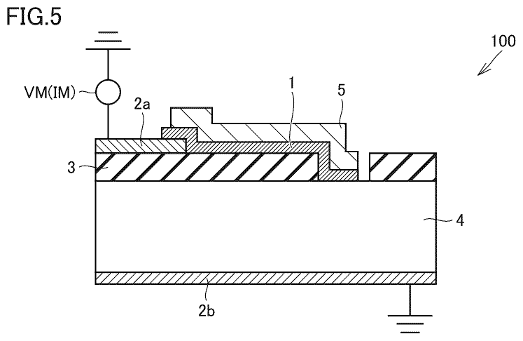

As illustrated in FIG. 5, one of first electrode portion 2a and second electrode portion 2b of electromagnetic wave detector 100 may be connected to voltmeter VM or an ammeter IM, and another of first electrode portion 2a and second electrode portion 2b may be grounded. Voltmeter VM detects the change in the electric resistance value of two-dimensional material layer 1 caused by the optical gate effect when thermoelectric conversion material layer 5 is irradiated with the electromagnetic wave as the voltage generated between first electrode portion 2a and second electrode portion 2b, to detect the electromagnetic wave. Ammeter IM detects the change in the electric resistance value of two-dimensional material layer 1 caused by the optical gate effect when thermoelectric conversion material layer 5 is irradiated with the electromagnetic wave as the current generated between first electrode portion 2a and second electrode portion 2b, to detect the electromagnetic wave.

A plurality of electromagnetic wave detectors 100 may be used in combination. The plurality of electromagnetic wave detectors 100 may have the same configuration with each other. For example, one or more electromagnetic wave detectors 100 among the plurality of electromagnetic wave detectors 100 are disposed in a shielded space that is not irradiated with the electromagnetic wave to be detected, and one or more of other electromagnetic wave detectors 100 among the plurality of electromagnetic wave detectors 100 are disposed in a space that is irradiated with the electromagnetic wave to be detected. In this case, if the latter electromagnetic wave detector 100 is irradiated with the electromagnetic wave, a difference in current I or voltage V can be detected between the former electromagnetic wave detector 100 and the latter electromagnetic wave detector 100. Even in this way, the electromagnetic wave can be detected.

### <Effects of Electromagnetic Wave Detector 100>

Electromagnetic wave detector 100 includes semiconductor layer 4, two-dimensional material layer 1 electrically connected to semiconductor layer 4, first electrode portion 2a electrically connected to two-dimensional material layer 1 without semiconductor layer 4 therebetween, second electrode portion 2b electrically connected to two-dimensional material layer 1 via semiconductor layer 4, and thermoelectric conversion material layer 5. Thermoelectric conversion material layer 5 is in contact with two-dimensional material layer 1.

In such electromagnetic wave detector 100, if thermoelectric conversion material layer 5 is irradiated with the electromagnetic wave, the potential difference is generated in thermoelectric conversion material layer 5 due to the thermoelectric power generation effect, further, the electrical resistance of two-dimensional material layer 1 is modulated due to the optical gate effect, and as a result, the photocurrent can be amplified in two-dimensional material layer 1.

A changed amount of the current generated in two-dimensional material layer 1 due to the optical gate effect caused by the generation of the potential difference in thermoelectric conversion material layer 5 is larger than a changed amount of a current in a normal semiconductor. In particular, in two-dimensional material layer 1, the current is greatly changed with respect to a slight change in the potential as compared with the normal semiconductor. For example, in a case where the single-layer graphene is used as two-dimensional material layer 1, the thickness of two-dimensional material layer 1 is equivalent to one atomic layer and extremely thin. Further, the mobility of the electrons in the single-layer graphene is large. In this case, the above changed amount of the current in two-dimensional material layer 1 calculated from, for example, the mobility of the electrons in and the thickness of two-dimensional material layer 1 is about several hundred times to several thousand times the changed amount of the current in the normal semiconductor.

Accordingly, by utilizing the optical gate effect, an extraction efficiency of the current detected in two-dimensional material layer 1 is greatly improved. Such optical gate effect does not directly enhance a quantum efficiency of the photoelectric conversion material such as the normal semiconductor, but the current is greatly changed due to the incidence of the electromagnetic wave. Therefore, the quantum efficiency of the above electromagnetic wave detector equivalently calculated from a differential current due to the incidence of the electromagnetic wave can exceed 100%. Accordingly, the detection sensitivity of the electromagnetic wave by electromagnetic wave detector 100 according to the present embodiment is higher than that of a conventional semiconductor electromagnetic wave detector or a graphene electromagnetic wave detector to which the optical gate effect is not applied.

Further, electromagnetic wave detector 100 further includes insulating film 3 that is in contact with a part of semiconductor layer 4 and has opening 30 that opens another part of semiconductor layer 4. Two-dimensional material layer 1 is electrically connected to the other part of semiconductor layer 4 at opening 30, and specifically, is in the Schottky junction with semiconductor layer 4. Since two-dimensional material layer 1 is in the Schottky junction with semiconductor layer 4, no current flows when the reverse bias is applied, and electromagnetic wave detector 100 can be turned off.

Further, in electromagnetic wave detector 100, since two-dimensional material layer 1 has a region disposed on insulating film 3, a conductivity of two-dimensional material layer 1 due to the above optical gate effect is more easily modulated as compared with a case where two-dimensional material layer 1 does not have the region disposed on insulating film 3.

Further, a changed amount of a current value I when electromagnetic wave detector 100 is irradiated with the electromagnetic wave includes an amount of the photocurrent generated by photoelectric conversion in two-dimensional material layer 1, in addition to a changed amount of a current generated due to a resistance change of two-dimensional material layer 1 due to the potential difference generated in thermoelectric conversion material layer 5 and a changed amount of a current generated due to a change in the energy barrier between two-dimensional material layer 1 and semiconductor layer 4. In other words, by irradiating thermoelectric conversion material layer 5 and two-dimensional material layer 1 with the electromagnetic wave, electromagnetic wave detector 100 can also detect the photocurrent due to the photoelectric conversion efficiency inherent in two-dimensional material layer 1 in addition to a current generated due to the optical gate effect described above and a current accompanying the change in the energy barrier.

As described above, in electromagnetic wave detector 100, both a favorable sensitivity with the quantum efficiency of greater than or equal to 100% and the OFF operation can be achieved.

Further, in electromagnetic wave detector 100, in a case where silicon is used for semiconductor layer 4, a read circuit can be formed in semiconductor layer 4. Accordingly, it is possible to read a signal without forming a circuit outside an element.

Further, thermoelectric conversion material layer 5 of electromagnetic wave detector 100 is in contact with each of first portion 1a, second portion 1b, and third portion 1c of two-dimensional material layer 1. In electromagnetic wave detector 100, a contact region between thermoelectric conversion material layer 5 and two-dimensional material layer 1 is wider than that in a case where thermoelectric conversion material layer 5 is in contact with only one of first portion 1a, second portion 1b, and third portion 1c of two-dimensional material layer 1, resulting in a high optical gate effect associated with the thermoelectric power generation effect.

Further, in electromagnetic wave detector 100, since first portion 1a of two-dimensional material layer 1 is in the Schottky junction with semiconductor layer 4, the dark current can be zero by adjusting the bias voltage applied between first electrode portion 2a and second electrode portion 2b to apply a reverse bias voltage to the Schottky junction. In other words, electromagnetic wave detector 100 can be turned off.

Preferably, thermoelectric conversion material layer 5 is arranged to generate an electric field in a direction perpendicular to the extending direction of two-dimensional material layer 1 when the electromagnetic wave to be detected is incident on thermoelectric conversion material layer 5. In this way, the rate of change in the electrical resistance of two-dimensional material layer 1 due to the optical gate effect is maximized.

Preferably, thermoelectric conversion material layer 5 is arranged to make the direction of the potential difference orthogonal to the two-dimensional surface of two-dimensional material layer 1 at at least one of the interface between two-dimensional material layer 1 and thermoelectric conversion material layer 5 and the junction interface between two-dimensional material layer 1 and semiconductor layer 4. Accordingly, it is possible to maximize the rate of change in the electrical resistance of two-dimensional material layer 1 due to the optical gate effect.

Preferably, in electromagnetic wave detector 100, the surface of thermoelectric conversion material layer 5 irradiated with the electromagnetic wave has the high flatness. Accordingly, since the temperature change speed of thermoelectric conversion material layer 5 can be designed to be as quick as possible, time from the incidence of the electromagnetic wave on the electromagnetic wave detector to the change in the resistance value in two-dimensional material layer 1 is shortened. Such electromagnetic wave detector 100 eliminates delay in the amplification due to the optical gate effect, and can speed up the response.

### Second Embodiment

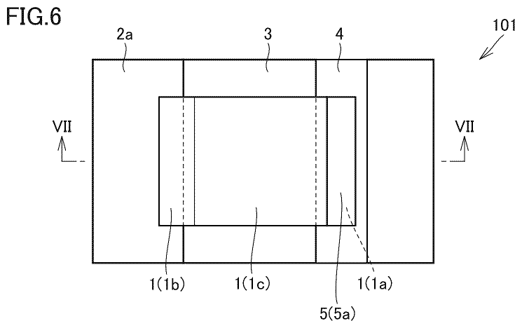

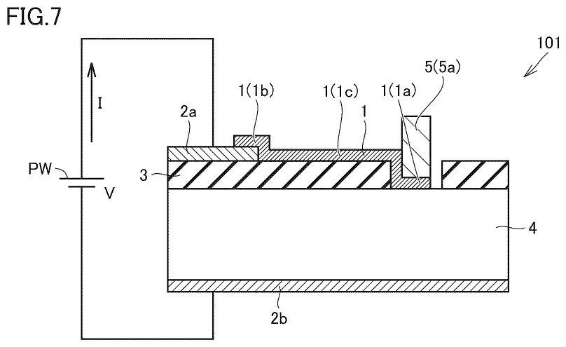

FIG. 6 is a schematic plan view of the electromagnetic wave detector according to the second embodiment. FIG. 7 is a schematic cross-sectional view taken along line VII-VII in FIG. 6.

An electromagnetic wave detector 101 illustrated in FIGS. 6 and 7 basically has a similar configuration to that of electromagnetic wave detector 100 illustrated in FIGS. 1 and 2 and can obtain similar effects, but is different from electromagnetic wave detector 100 illustrated in FIGS. 1 and 2 in that thermoelectric conversion material layer 5 is not in contact with any of first portion 1a, second portion 1b, and third portion 1c of two-dimensional material layer 1. Hereinafter, differences between the electromagnetic wave detector according to the second embodiment and electromagnetic wave detector 100 will be mainly described.

Electromagnetic wave detector 101 illustrated in FIGS. 6 and 7 is different from electromagnetic wave detector 100 in that thermoelectric conversion material layer 5 is disposed to overlap with only the first portion of two-dimensional material layer 1 and in contact with only the first portion. In electromagnetic wave detector 101, thermoelectric conversion material layer 5 is disposed only on the junction interface between two-dimensional material layer 1 and semiconductor layer 4. Thermoelectric conversion material layer 5 includes only fourth portion 5a and is not in contact with second portion 1b and third portion 1c of two-dimensional material layer 1.

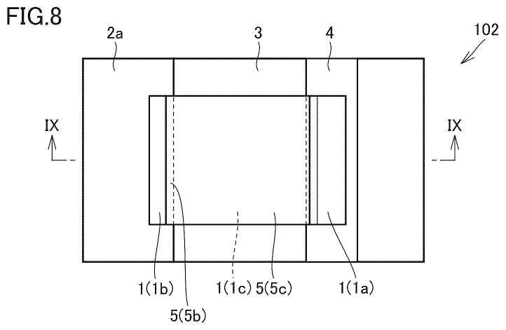

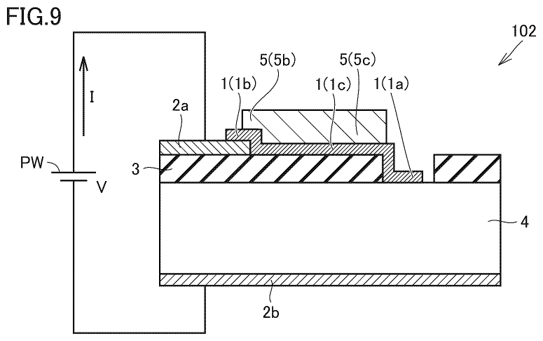

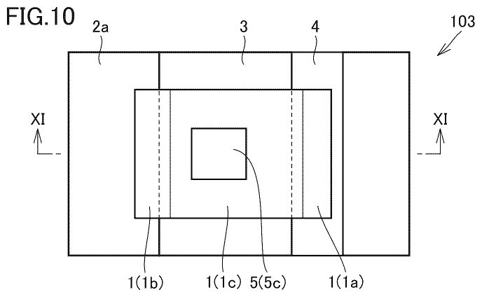

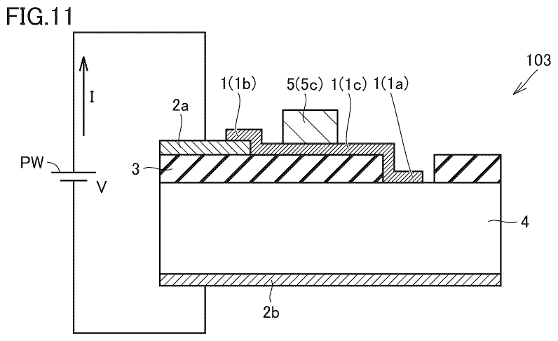

FIG. 8 is a schematic plan view illustrating an electromagnetic wave detector 102 according to a first variation of the present embodiment. FIG. 9 is a schematic cross-sectional view taken along line IX-IX in FIG. 8. FIG. 10 is a schematic plan view illustrating an electromagnetic wave detector 103 according to a second variation of the present embodiment. FIG. 11 is a schematic cross-sectional view taken along line XI-XI in FIG. 10.

In electromagnetic wave detector 102 illustrated in FIGS. 8 and 9, thermoelectric conversion material layer 5 is in contact with only second portion 1b and third portion 1c of two-dimensional material layer 1. Thermoelectric conversion material layer 5 is disposed only on two-dimensional material layer 1 disposed on insulating film 3. Thermoelectric conversion material layer 5 includes only fifth portion 5b and sixth portion Sc, and is not in contact with first portion 1a of two-dimensional material layer 1.

In electromagnetic wave detector 103 illustrated in FIGS. 10 and 11, thermoelectric conversion material layer 5 is in contact with only third portion 1c of two-dimensional material layer 1. Thermoelectric conversion material layer 5 includes only sixth portion 5c, and is not in contact with first portion 1a and second portion 1b of two-dimensional material layer 1.

Note that, in the electromagnetic wave detector according to the present embodiment, thermoelectric conversion material layer 5 may be in contact with only second portion 1b of two-dimensional material layer 1. Thermoelectric conversion material layer 5 may include only fifth portion 5b.

### <Operation and Effect>

In electromagnetic wave detector 101, thermoelectric conversion material layer 5 is disposed on the junction interface between two-dimensional material layer 1 and semiconductor layer 4. In this case, when the electromagnetic wave is incident on thermoelectric conversion material layer 5, the energy barrier between two-dimensional material layer 1 and semiconductor layer 4 can be changed due to the potential difference of thermoelectric conversion material layer 5, resulting in high detection sensitivity of electromagnetic wave detector 101.

Further, in electromagnetic wave detector 102, thermoelectric conversion material layer 5 is disposed on two-dimensional material layer 1 on insulating film 3. In this case, when the electromagnetic wave is incident on thermoelectric conversion material layer 5, the conductivity of two-dimensional material layer 1 is modulated by the potential difference of thermoelectric conversion material layer 5, resulting in high detection sensitivity of electromagnetic wave detector 102.

Further, in electromagnetic wave detector 103, thermoelectric conversion material layer 5 is disposed on a part of two-dimensional material layer 1. In this case, when the electromagnetic wave is incident on thermoelectric conversion material layer 5, the conductivity is modulated near the region in contact with thermoelectric conversion material layer 5. Accordingly, the conductivity can be modulated in any region of two-dimensional material layer 1.

A configuration of the electromagnetic wave detector according to the present embodiment can also be applied to other embodiments.

### Third Embodiment

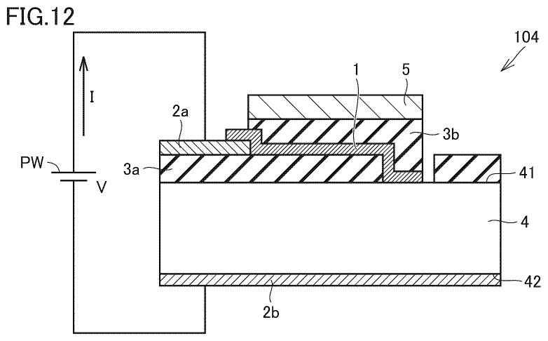

FIG. 12 is a schematic cross-sectional view of the electromagnetic wave detector according to the third embodiment. An electromagnetic wave detector 104 illustrated in FIG. 12 basically has a similar configuration to that of the electromagnetic wave detector illustrated in FIGS. 1 and 2 and can obtain similar effects, but is different from electromagnetic wave detector 100 illustrated in FIGS. 1 and 2 in that thermoelectric conversion material layer S is spaced apart from two-dimensional material layer 1 in a direction orthogonal to first surface 41. Hereinafter, differences of the electromagnetic wave detector according to the third embodiment from electromagnetic wave detector 100 will be mainly described.

As illustrated in FIG. 12, thermoelectric conversion material layer 5 is not in direct contact with two-dimensional material layer 1. Electromagnetic wave detector 104 further includes an insulating film 3b that separates two-dimensional material layer 1 and thermoelectric conversion material layer 5. Each of the first portion, second portion 1b, and third portion 1c of two-dimensional material layer 1 is spaced apart from thermoelectric conversion material layer 5.

A thickness of insulating film 3b is set to achieve the state where the gate voltage is applied in a pseudo manner to two-dimensional material layer 1 due to the potential difference generated inside thermoelectric conversion material layer 5. The thickness of insulating film 3b is, for example, greater than or equal to 0.1 μm and less than or equal to 10 μm.

In the electromagnetic wave detector according to the third embodiment, at least a part of thermoelectric conversion material layer 5 may be spaced apart from two-dimensional material layer 1 in the direction orthogonal to first surface 41.

### <Operation and Effect>

In the above electromagnetic wave detector, insulating film 3b is disposed between thermoelectric conversion material layer 5 and two-dimensional material layer 1.

By inserting insulating film 3b between thermoelectric conversion material layer 5 and two-dimensional material layer 1, thermoelectric conversion material layer 5 is not in direct contact with two-dimensional material layer 1. In a case where thermoelectric conversion material layer 5 is in direct contact with two-dimensional material layer 1, the charge is exchanged between thermoelectric conversion material layer 5 and two-dimensional material layer 1, resulting in weak optical response. Further, in a case where thermoelectric conversion material layer 5 is in contact with two-dimensional material layer 1, hysteresis may occur, and the response speed of the electromagnetic wave detector may be reduced. These effects can be suppressed by inserting insulating film 3b. Further, even in a case where insulating film 3b is inserted, it is possible to apply the change in the electric field due to the generation of the potential difference caused by the temperature difference of thermoelectric conversion material layer 5 to two-dimensional material layer 1.

Further, in a case where insulating film 3b absorbs the electromagnetic wave having the detection wavelength to generate heat, it is possible to increase the temperature difference generated by applying thermal energy to thermoelectric conversion material layer 5 through heat generation of insulating film 3b, and increase the sensitivity of the electromagnetic wave detector.

Here, the configuration of the electromagnetic wave detector according to the present embodiment can also be applied to other embodiments.

### Fourth Embodiment

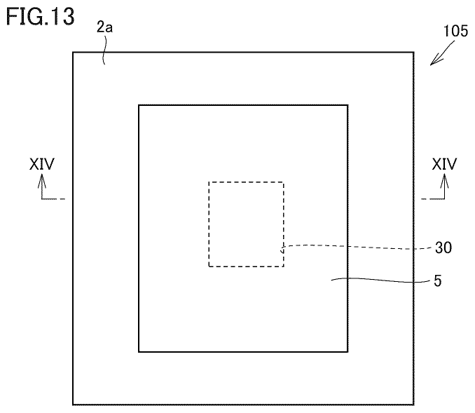

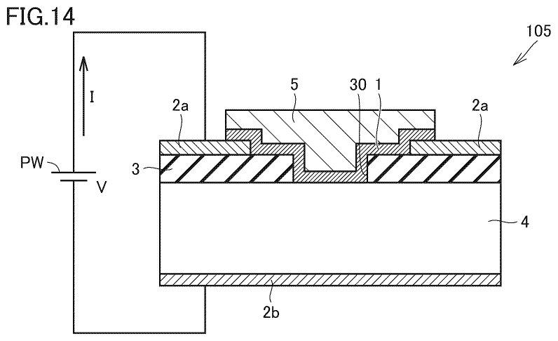

FIG. 13 is a plan view of the electromagnetic wave detector according to the fourth embodiment. FIG. 14 is the cross-sectional view taken along line XIV-XIV in FIG. 13. An electromagnetic wave detector 105 illustrated in FIGS. 13 and 14 basically has a similar configuration to that of the electromagnetic wave detector illustrated in FIGS. 1 and 2 and can obtain similar effects, but is different from electromagnetic wave detector 100 illustrated in FIGS. 1 and 2 in that first electrode portion 2a is formed in an annular shape and first portion 1a is disposed on an inner side than first electrode portion 2a in plan view. Hereinafter, differences between the electromagnetic wave detector according to the fourth embodiment and electromagnetic wave detector 100 will be mainly described.

For example, electromagnetic wave detector 105 illustrated in FIG. 13 is considered as one pixel. First electrode portion 2a is disposed, for example, on an outer peripheral portion of the above pixel. In plan view, opening 30 of insulating film 3 is disposed on an inner side than first electrode portion 2a, and disposed at a center of the above pixel, for example. First electrode portion 2a is disposed on the upper surface of insulating film 3 to surround an outer periphery of opening 30 of insulating film 3.

### <Operation and Effect>

In electromagnetic wave detector 105 illustrated in FIG. 13, while attenuation of the electromagnetic wave by first electrode portion 2a is suppressed, a region affected by the change in the electric field from semiconductor layer 4 in two-dimensional material layer 1 can be widened as compared with electromagnetic wave detector 100 illustrated in FIG. 1. Therefore, in electromagnetic wave detector 105, the photocurrent extracted from semiconductor layer 4 via two-dimensional material layer 1 increases as compared with electromagnetic wave detector 10, resulting in high detection sensitivity.

Preferably, an area of first electrode portion 2a occupying the above pixel in plan view (hereinafter, also referred to as occupied area) is smaller than an area of thermoelectric conversion material layer 5 occupying the above pixel in plan view. Preferably, a shortest distance between an inner peripheral end and an outer peripheral end of first electrode portion 2a in plan view is shorter than a minimum width of thermoelectric conversion material layer 5 in plan view. As the occupied area of first electrode portion 2a in plan view decreases, it is possible to suppress the attenuation of the electromagnetic wave incident on thermoelectric conversion material layer 5 in a case where the electromagnetic wave is incident on thermoelectric conversion material layer 5 from first electrode portion 2a side.

In plan view, two-dimensional material layer 1 is disposed to overlap with the entire inner side of first electrode portion 2a and at least an inner peripheral edge of first electrode portion 2a. In plan view, two-dimensional material layer 1 may be disposed to substantially overlap with the entire first surface 41 of semiconductor layer 4.

### Fifth Embodiment

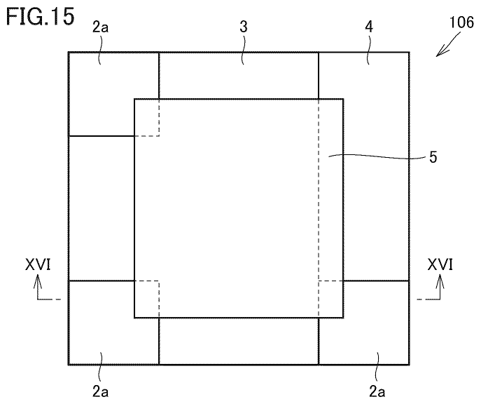

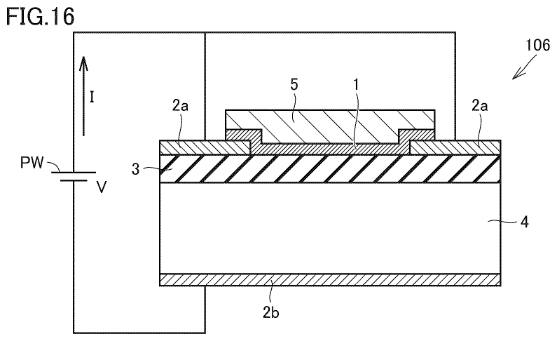

FIG. 15 is the plan view of the electromagnetic wave detector according to the fifth embodiment. FIG. 16 is the cross-sectional view taken along line XVI-XVI in FIG. 15. An electromagnetic wave detector 106 illustrated in FIGS. 15 and 16 basically has a similar configuration to that of the electromagnetic wave detector illustrated in FIGS. 1 and 2 and can obtain similar effects, but is different from electromagnetic wave detector 100 illustrated in FIGS. 1 and 2 in that electromagnetic wave detector 106 includes a plurality of first electrode portions 2a electrically connected to two-dimensional material layer 1 and a plurality of connection portions between two-dimensional material layer 1 and first electrode portions 2a are arranged. Hereinafter, differences between the electromagnetic wave detector according to the fifth embodiment and electromagnetic wave detector 100 will be mainly described.

As illustrated in FIG. 15, electromagnetic wave detector 106 includes the plurality of (for example, three) first electrode portion 2a. As illustrated in FIGS. 15 and 16, each of the plurality of first electrode portions 2a has a configuration equivalent to each other. Each of the plurality of first electrode portion 2a is electrically connected to two-dimensional material layer 1. Each of the plurality of first electrode portions 2a is connected in parallel to each other. In plan view, each of the plurality of first electrode portions 2a is disposed, for example, on an outer peripheral portion of electromagnetic wave detector 106. In a case where a planar shape of electromagnetic wave detector 106 is polygonal, each of the plurality of first electrode portion 2a is disposed, for example, at a corner of the planar shape of electromagnetic wave detector 106. In a case where the planar shape of electromagnetic wave detector 106 is quadrangular, each of the plurality of first electrode portion 2a may be disposed at two or more corners among four corners, or may be disposed at each of the four corners. Note that, in plan view, the plurality of first electrode portions 2a may be disposed at any position.

### <Operation and Effect>

In electromagnetic wave detector 106, since the plurality of connection portions between two-dimensional material layer 1 and first electrode portion 2a are arranged, a current flowing between semiconductor layer 4 and first electrode portion 2a through two-dimensional material layer 1 does not locally flow and is widely dispersed in two-dimensional material layer 1 as compared with a case where only one connection portion is arranged. Therefore, a region receiving the optical gate effect becomes wider in two-dimensional material layer 1. As a result, detection sensitivity of electromagnetic wave detector 106 increases.

### Sixth Embodiment

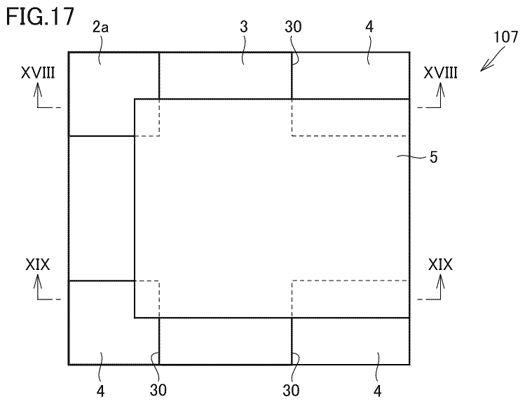

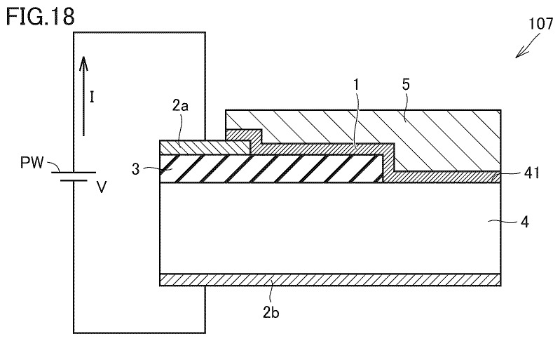

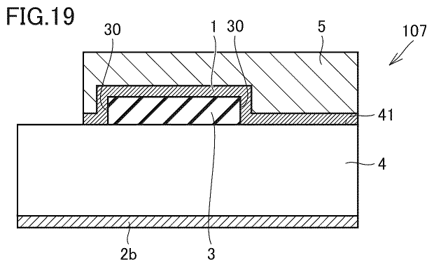

FIG. 17 is the plan view of the electromagnetic wave detector according to the sixth embodiment. FIG. 18 is the cross-sectional view taken along line XVIII-XVIII in FIG. 17. FIG. 19 is a schematic cross-sectional view taken along line XIX-XIX in FIG. 17. An electromagnetic wave detector 107 illustrated in FIGS. 17, 18, and 19 basically has a similar configuration to that of the electromagnetic wave detector illustrated in FIGS. 1 and 2 and can obtain similar effects, but is different from electromagnetic wave detector 100 illustrated in FIGS. 1 and 2 in that the plurality of connection portions between two-dimensional material layer 1 and semiconductor layer 4 are arranged. Hereinafter, differences between the electromagnetic wave detector according to the sixth embodiment and electromagnetic wave detector 100 will be mainly described.

In electromagnetic wave detector 107 illustrated in FIG. 17, a plurality of (for example, three) openings 30 are formed in insulating film 3. Each of the plurality of openings 30 is formed to expose a part of first surface 41 of semiconductor layer 4.

As illustrated in FIG. 17, the plurality of openings 30 are spaced apart from each other in plan view. In plan view, each of the plurality of openings 30 is disposed, for example, on an outer peripheral portion of electromagnetic wave detector 107. In plan view, first electrode portion 2a is spaced apart from each of the plurality of openings 30, for example, in the outer peripheral portion of electromagnetic wave detector 107. The occupied area of first electrode portion 2a in plan view is smaller than a sum of opening areas of the plurality of openings 30.

Two-dimensional material layer 1 extends from the upper surface of insulating film 3 to an inner portion of each of the plurality of openings 30, and is electrically connected to semiconductor layer 4 inside each of the plurality of openings 30. Two-dimensional material layer 1 is in contact with semiconductor layer 4 inside each of the plurality of openings 30. In plan view, each of two-dimensional material layer 1 and thermoelectric conversion material layer 5 extends over each of the plurality of openings 30.

### <Operation and Effect>

In electromagnetic wave detector 107, since the plurality of connection portions between two-dimensional material layer 1 and semiconductor layer 4 are arranged, the current flowing between semiconductor layer 4 and first electrode portion 2a through two-dimensional material layer 1 does not locally flow and is widely dispersed in two-dimensional material layer 1 as compared with the case where only one connection portion is arranged. Therefore, the region receiving the optical gate effect becomes wider in two-dimensional material layer 1. As a result, detection sensitivity of electromagnetic wave detector 107 increases.

Further, in electromagnetic wave detector 107, similarly to electromagnetic wave detector 106 illustrated in FIG. 15, first electrode portion 2a is spaced apart from each of the plurality of openings 30 on the outer peripheral portion of electromagnetic wave detector 107 in plan view. The occupied area of first electrode portion 2a in plan view is smaller than the sum of the opening areas of the plurality of openings 30.

In this way, in the case where the electromagnetic wave is incident on thermoelectric conversion material layer 5 from first electrode portion 2a side, the attenuation of the electromagnetic wave incident on thermoelectric conversion material layer 5 can be suppressed.

### Seventh Embodiment

In the electromagnetic wave detector according to the first embodiment, positions of the end portions of two-dimensional material layer 1 in plan view are not particularly limited, but in the electromagnetic wave detector according to the seventh embodiment, first portion 1a of two-dimensional material layer 1 has the end portion of two-dimensional material layer 1 in plan view. The electromagnetic wave detector according to the seventh embodiment basically has a similar configuration to that of the electromagnetic wave detector illustrated in FIGS. 1 and 2 and can obtain similar effects, but is different from electromagnetic wave detector 100 in that the end portion of two-dimensional material layer 1 is disposed on semiconductor layer 4. In other words, the connection portions between two-dimensional material layer 1 and semiconductor layer 4 have the end portion of two-dimensional material layer 1 in plan view.

The end portion of two-dimensional material layer 1 in plan view is disposed in the opening of insulating film 3. The above end portion of two-dimensional material layer 1 is, for example, an end portion of two-dimensional material layer 1 in the longitudinal direction.

A shape of the end portion of two-dimensional material layer 1 in plan view is, for example, rectangular, but may be triangular, comb-shaped, or the like.

Two-dimensional material layer 1 may have a plurality of end portions electrically connected to semiconductor layer 4. Further, first portion 1a of two-dimensional material layer 1 may have only a part of the end portion of two-dimensional material layer 1 in plan view. For example, the end portion of two-dimensional material layer 1 in plan view may have a portion disposed in the opening of insulating film 3 and a portion disposed on insulating film 3.

Further, the above end portion of two-dimensional material layer 1 may be the graphene nanoribbon. In this case, since the graphene nanoribbon has a band gap, the Schottky junction is formed in a junction region between the graphene nanoribbon and a semiconductor portion. Therefore, it is possible to reduce the dark current and improve the sensitivity of the electromagnetic wave detector.

### <Operation and Effect>

In the electromagnetic wave detector according to the present embodiment, the end portion of two-dimensional material layer 1 in plan view exists on semiconductor layer 4. In this case, the junction region between two-dimensional material layer 1 and the semiconductor portion is in the Schottky junction. As a result, it is possible to reduce the dark current of the electromagnetic wave detector and improve the sensitivity by causing two-dimensional material layer 1 and the semiconductor portion to operate in the reverse bias. Further, by causing two-dimensional material layer 1 and the semiconductor portion to operate in a forward bias, it is possible to amplify the photocurrent to be extracted and improve the sensitivity.

Here, the configuration of the electromagnetic wave detector according to the present embodiment can also be applied to other embodiments.

### Eighth Embodiment

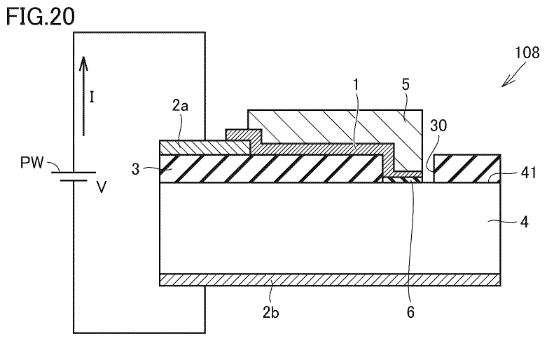

FIG. 20 is the cross-sectional view of the electromagnetic wave detector according to the eighth embodiment. An electromagnetic wave detector 108 illustrated in FIG. 20 basically has a similar configuration to that electromagnetic wave detector 100 illustrated in FIGS. 1 and 2 and can obtain similar effects, but is different from electromagnetic wave detector 100 in that electromagnetic wave detector 108 further includes a tunnel insulating layer 6 disposed between two-dimensional material layer 1 and semiconductor layer 4. Hereinafter, differences between electromagnetic wave detector 108 and electromagnetic wave detector 100 will be mainly described.

Tunnel insulating layer 6 is disposed inside opening 30 of insulating film 3. A thickness of tunnel insulating layer 6 is set to generate a tunnel current between two-dimensional material layer 1 and semiconductor layer 4 when the electromagnetic wave to be detected is incident on two-dimensional material layer 1 and thermoelectric conversion material layer 5. The thickness of tunnel insulating layer 6 is, for example, greater than or equal to 1 nm and less than or equal to 10 nm.

A material constituting tunnel insulating layer 6 may be any material having the electrical insulation property, and includes, for example, at least one selected from the group consisting of metal oxides such as alumina and hafnium oxide, or oxides including semiconductors such as silicon oxide and silicon nitride, and nitrides such as boron nitride. Any method can be used as a manufacturing method of tunnel insulating layer 6. For example, tunnel insulating layer 6 may be manufactured by using an atomic layer deposition (ALD) method, a vacuum deposition method, the sputtering method, or the like. Alternatively, tunnel insulating layer 6 may be formed by oxidizing or nitriding a surface of semiconductor layer 4. Alternatively, a natural oxide film formed on the surface of semiconductor layer 4 may be used as tunnel insulating layer 6.

Here, the configuration of the electromagnetic wave detector according to the present embodiment can also be applied to other embodiments.

### <Operation and Effect>

Since electromagnetic wave detector 108 includes tunnel insulating layer 6 disposed between two-dimensional material layer 1 and semiconductor layer 4, a leakage current at the junction interface between semiconductor layer 4 and two-dimensional material layer 1 is suppressed, and the dark current can be reduced.

The thickness of tunnel insulating layer 6 is set to generate the tunnel current between two-dimensional material layer 1 and semiconductor layer 4 when the electromagnetic wave to be detected is incident on two-dimensional material layer 1 and thermoelectric conversion material layer 5. In this way, since tunnel injection occurs from semiconductor layer 4 to two-dimensional material layer 1, and a relatively large photocurrent can be injected from semiconductor layer 4 to two-dimensional material layer 1, sensitivity of electromagnetic wave detector 108 is increased.

### Ninth Embodiment

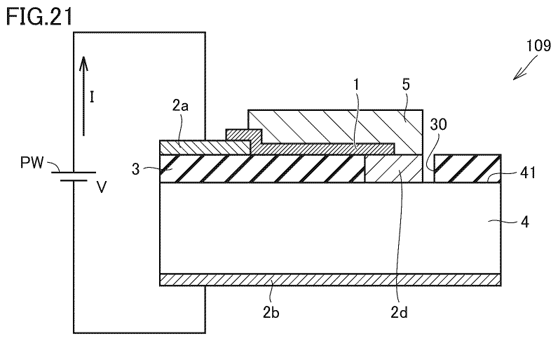

FIG. 21 is a schematic cross-sectional view of the electromagnetic wave detector according to the ninth embodiment. An electromagnetic wave detector 109 illustrated in FIG. 21 basically has a similar configuration to that the electromagnetic wave detector illustrated in FIGS. 1 and 2 and can obtain similar effects, but is different from electromagnetic wave detector 100 in that electromagnetic wave detector 109 further includes a connection conductor portion (a conductive member) 2d that electrically connects two-dimensional material layer 1 and semiconductor layer 4. Hereinafter, differences between electromagnetic wave detector 109 and electromagnetic wave detector 100 will be mainly described.

Connection conductor portion 2d is disposed inside opening 30 of insulating film 3. In plan view, connection conductor portion 2d is disposed to overlap with each of two-dimensional material layer 1 and semiconductor layer 4, and in contact with each of two-dimensional material layer 1 and semiconductor layer 4. A lower surface of connection conductor portion 2d is in contact with first surface 41 of semiconductor layer 4. An upper surface of connection conductor portion 2d is in contact with the lower surface of two-dimensional material layer 1. Preferably, connection conductor portion 2d is in the Schottky junction with semiconductor layer 4.

Preferably, a position of the upper surface of connection conductor portion 2d is substantially the same as a position of the upper surface of insulating film 3. In other words, preferably, a thickness of connection conductor portion 2d is equal to the thickness of insulating film 3. In this case, two-dimensional material layer 1 extends in a planar shape from the upper surface of insulating film 3 to the upper surface of connection conductor portion 2d without being bent.

Thermoelectric conversion material layer 5 is in contact with, for example, connection conductor portion 2d. Note that thermoelectric conversion material layer 5 may not be in contact with connection conductor portion 2d.

In a case where the electromagnetic wave is incident on thermoelectric conversion material layer 5 from connection conductor portion 2d side, connection conductor portion 2d preferably exhibits a high transmittance at the wavelength of the electromagnetic wave detected by the electromagnetic wave detector.

Here, the configuration of the electromagnetic wave detector according to the present embodiment can also be applied to other embodiments.

### <Operation and Effect>

In electromagnetic wave detector 109, since semiconductor layer 4 and two-dimensional material layer 1 are electrically connected via connection conductor portion 2d, a contact resistance between two-dimensional material layer 1 and semiconductor layer 4 can be reduced as compared with a case where connection conductor portion 2d is not included.

Further, if connection conductor portion 2d is in the Schottky junction with semiconductor layer 4, the dark current can be reduced.

Further, if the thickness of connection conductor portion 2d is equal to the thickness of insulating film 3, the two-dimensional surfaces of first portion 1a and third portion 1c of two-dimensional material layer 1 extend in the same direction, resulting in improvement of the mobility of the carriers in two-dimensional material layer 1.

The optical gate effect is proportional to the mobility of the carriers in two-dimensional material layer 1. Therefore, detection sensitivity of electromagnetic wave detector 109 can be improved as compared with electromagnetic wave detector 100.

### Tenth Embodiment

### <Configuration of Electromagnetic Wave Detector>

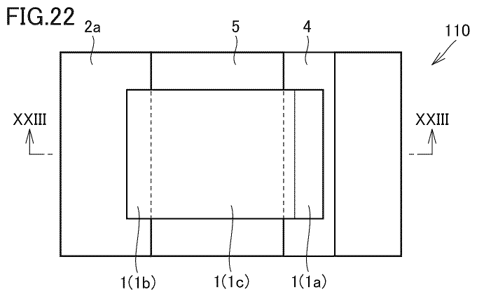

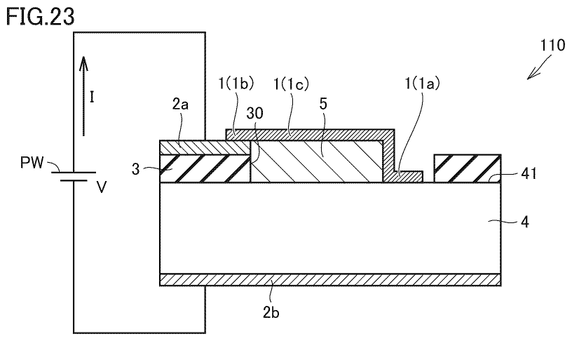

FIG. 22 is a schematic plan view of the electromagnetic wave detector according to the tenth embodiment. FIG. 23 is a schematic cross-sectional view taken along line XXIII-XXIII in FIG. 22. An electromagnetic wave detector 110 illustrated in FIGS. 22 and 23 basically has a similar configuration to that of electromagnetic wave detector 100 illustrated in FIGS. 1 and 2 and can obtain similar effects, but is different from electromagnetic wave detector 100 in that thermoelectric conversion material layer 5 is disposed closer to semiconductor layer 4 than two-dimensional material layer 1. Hereinafter, differences between electromagnetic wave detector 110 and electromagnetic wave detector 100 will be mainly described.

As illustrated in FIGS. 22 and 23, thermoelectric conversion material layer 5 is disposed between first surface 41 of semiconductor layer 4 and the lower surface of two-dimensional material layer 1. Thermoelectric conversion material layer 5 is in contact with, for example, first surface 41. Thermoelectric conversion material layer 5 is in contact with third portion 1c of two-dimensional material layer 1. Third portion 1c connecting first portion 1a and second portion 1b in two-dimensional material layer 1 is disposed on thermoelectric conversion material layer 5. Thermoelectric conversion material layer 5 is disposed, for example, inside opening 30 of insulating film 3. In plan view, thermoelectric conversion material layer 5 is not disposed to overlap with insulating film 3. In plan view, insulating film 3 is disposed to overlap with only second portion 1b and first electrode portion 2a of two-dimensional material layer 1.

Preferably, the thickness of thermoelectric conversion material layer 5 is equal to a sum of the thickness of insulating film 3 and the thickness of first electrode portion 2a.

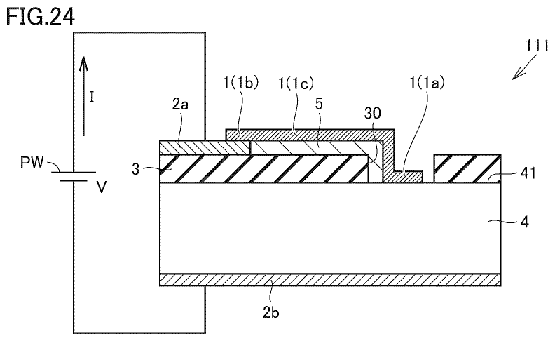

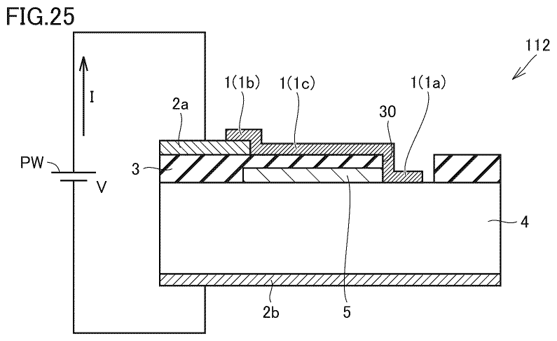

FIG. 24 is a schematic cross-sectional view illustrating an electromagnetic wave detector 111 according to the first variation of the tenth embodiment. FIG. 25 is a schematic cross-sectional view illustrating an electromagnetic wave detector 112 according to the second variation of the tenth embodiment.

Each of electromagnetic wave detector 111 illustrated in FIG. 24 and electromagnetic wave detector 112 illustrated in FIG. 25 basically has a similar configuration to that of electromagnetic wave detector 110 illustrated in FIGS. 22 and 23, but is different from electromagnetic wave detector 110 in that thermoelectric conversion material layer 5 is disposed to overlap with a part of insulating film 3.

As illustrated in FIG. 24, in electromagnetic wave detector 111, thermoelectric conversion material layer 5 is disposed between insulating film 3 and third portion 1c of two-dimensional material layer 1. Thermoelectric conversion material layer 5 is in contact with, for example, first surface 41 of semiconductor layer 4. Note that thermoelectric conversion material layer 5 may not be in contact with first surface 41 of semiconductor layer 4.

As illustrated in FIG. 25, in electromagnetic wave detector 112, thermoelectric conversion material layer 5 is disposed between first surface 41 of semiconductor layer 4 and the lower surface of insulating film 3. Thermoelectric conversion material layer 5 is in contact with first surface 41 of semiconductor layer 4.

In electromagnetic wave detectors 110, 111, and 112, thermoelectric conversion material layer 5 may be arranged to make a direction of the above potential difference along a horizontal direction with respect to the junction interface between two-dimensional material layer 1 and semiconductor layer 4. In this case, when thermoelectric conversion material layer 5 is irradiated with the electromagnetic wave, the energy barrier between two-dimensional material layer 1 and semiconductor layer 4 changes due to the thermoelectric power generation effect, and the changed amount of current I can include the changed amount of the current accompanying the change in the energy barrier.

In electromagnetic wave detectors 110, 111, and 112, thermoelectric conversion material layer 5 may be arranged to make the direction of the above potential difference along a direction perpendicular to the junction interface between insulating film 3 and two-dimensional material layer 1. In this case, when thermoelectric conversion material layer 5 is irradiated with the electromagnetic wave, the conductivity of two-dimensional material layer 1 changes due to the optical gate effect associated with the thermoelectric power generation effect, and the photocurrent can be amplified.

In electromagnetic wave detectors 110, 111, and 112, thermoelectric conversion material layer 5 may have a portion arranged to make the direction of the above potential difference along the horizontal direction with respect to the junction interface between two-dimensional material layer 1 and semiconductor layer 4, and a portion arranged to make the direction of the above potential difference along the direction perpendicular to the junction interface between insulating film 3 and two-dimensional material layer 1.

Here, the configuration of the electromagnetic wave detector according to the present embodiment can also be applied to other embodiments. For example, in electromagnetic wave detectors 110, 111, and 112, thermoelectric conversion material layer 5 may not be in contact with two-dimensional material layer 1. In this case, similar effects to those of the third embodiment are further achieved.

### <Operation and Effect>

In electromagnetic wave detectors 110, 111, and 112, thermoelectric conversion material layer 5 is disposed closer to semiconductor layer 4 than two-dimensional material layer 1. In a manufacturing method of such electromagnetic wave detectors 110, 111, and 112, a step of forming two-dimensional material layer 1 can be performed after a step of forming thermoelectric conversion material layer 5. Therefore, in electromagnetic wave detectors 110, 111, and 112, since two-dimensional material layer 1 does not receive process damage due to the step of forming thermoelectric conversion material layer 5, performance of two-dimensional material layer 1 is not deteriorated. As a result, detection sensitivity of electromagnetic wave detectors 110, 111, and 112 can become higher than the detection sensitivity of electromagnetic wave detector 100.

In electromagnetic wave detector 110, preferably, the thickness of thermoelectric conversion material layer 5 is equal to the sum of the thickness of insulating film 3 and the thickness of first electrode portion 2a. Since the two-dimensional surfaces of second portion 1b and third portion 1c of two-dimensional material layer 1 extend in the same direction, the mobility of the carriers in two-dimensional material layer 1 is improved.

### Eleventh Embodiment

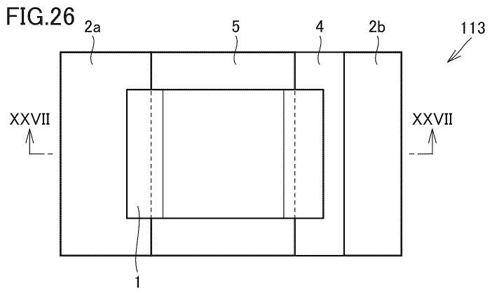

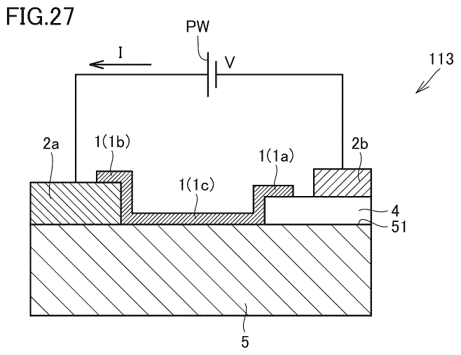

FIG. 26 is a schematic plan view of the electromagnetic wave detector according to the eleventh embodiment. FIG. 27 is a schematic cross-sectional view taken along line segment XXVII-XXVII in FIG. 26. An electromagnetic wave detector 113 illustrated in FIGS. 26 and 27 basically has a similar configuration to that of electromagnetic wave detector 110 illustrated in FIGS. 22 and 23 and can obtain similar effects, but is different from electromagnetic wave detector 110 in that semiconductor layer 4, two-dimensional material layer 1, first electrode portion 2a, and second electrode portion 2b are disposed on thermoelectric conversion material layer 5. Hereinafter, differences between electromagnetic wave detector 113 and electromagnetic wave detector 110 will be mainly described.

Thermoelectric conversion material layer 5 has a third surface 51. Semiconductor layer 4, two-dimensional material layer 1, first electrode portion 2a, and second electrode portion 2b are disposed on third surface 51 of thermoelectric conversion material layer 5. Semiconductor layer 4 is spaced apart from first electrode portion 2a on third surface 51. Third portion 1c of two-dimensional material layer 1 is in contact with third surface 51 of thermoelectric conversion material layer 5. Second electrode portion 2b is spaced apart from first portion 1a of two-dimensional material layer 1 on semiconductor layer 4.

Thermoelectric conversion material layer 5 forms a substrate on which semiconductor layer 4, two-dimensional material layer 1, first electrode portion 2a, and second electrode portion 2b are mounted. Thermoelectric conversion material layer 5 can include a thermoelectric conversion material crystal substrate.

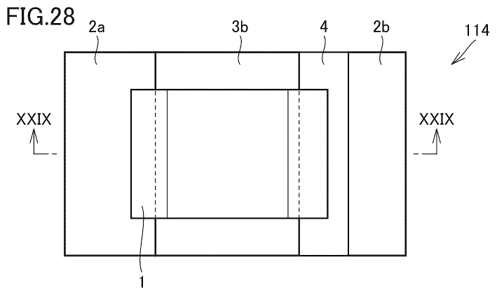

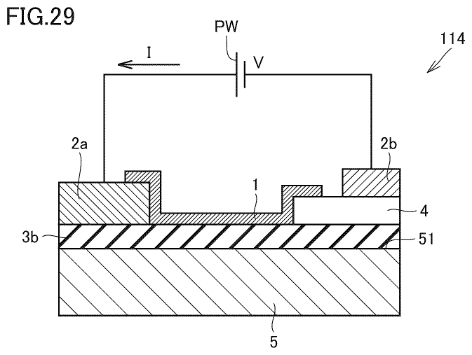

FIG. 28 is a plan view illustrating an electromagnetic wave detector 114 according to a variation of the eleventh embodiment. FIG. 29 is a schematic cross-sectional view taken along line XXIX-XXIX in FIG. 28.

Electromagnetic wave detector 114 illustrated in FIGS. 28 and 29 basically has a similar configuration to that of electromagnetic wave detector 113 illustrated in FIGS. 26 and 27, but is different from electromagnetic wave detector 113 in that electromagnetic wave detector 114 further includes insulating film 3b that separates two-dimensional material layer 1 and thermoelectric conversion material layer 5. From a different viewpoint, electromagnetic wave detector 114 is different from electromagnetic wave detector 104 illustrated in FIG. 12 in that semiconductor layer 4, two-dimensional material layer 1, first electrode portion 2a, and second electrode portion 2b are disposed on thermoelectric conversion material layer 5.

As illustrated in FIG. 29, insulating film 3b is disposed on third surface 51 of thermoelectric conversion material layer 5. First electrode portion 2a and semiconductor layer 4 are spaced apart from each other on insulating film 3b.

### <Operation and Effect>

In electromagnetic wave detector 113 and electromagnetic wave detector 114, since thermoelectric conversion material layer 5 can include the thermoelectric conversion material crystal substrate, crystallinity of thermoelectric conversion material layer 5 can be enhanced and thermoelectric conversion material layer 5 can be thickened as compared with a case where thermoelectric conversion material layer 5 does not include the thermoelectric conversion material crystal substrate. The temperature difference generated in thermoelectric conversion material layer 5 by irradiating such thermoelectric conversion material layer 5 with the electromagnetic wave is larger than that of thermoelectric conversion material layer 5 without being configured as the thermoelectric conversion material crystal substrate, resulting in improvement of the detection sensitivity.

Note that since electromagnetic wave detector 113 and electromagnetic wave detector 114 can obtain similar effects to those of electromagnetic wave detector 110, two-dimensional material layer 1 does not receive the process damage due to the step of forming thermoelectric conversion material layer 5 by two-dimensional material layer 1 also in electromagnetic wave detector 113.

Here, the configuration of the electromagnetic wave detector according to the present embodiment can also be applied to other embodiments.

### Twelfth Embodiment

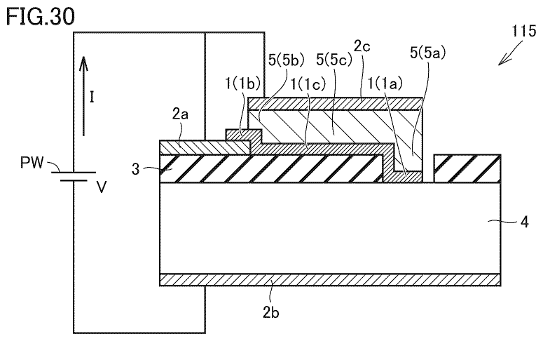

FIG. 30 is a schematic cross-sectional view of the electromagnetic wave detector according to the twelfth embodiment. An electromagnetic wave detector 115 illustrated in FIG. 30 basically has a similar configuration to that of electromagnetic wave detector 100 illustrated in FIGS. 1 and 2 and can obtain similar effects, but is different from electromagnetic wave detector 100 in that electromagnetic wave detector 115 further includes a third electrode portion 2c electrically connected to thermoelectric conversion material layer 5. Hereinafter, differences between electromagnetic wave detector 115 and electromagnetic wave detector 100 will be mainly described.

Third electrode portion 2c is disposed on thermoelectric conversion material layer 5. Third electrode portion 2c is disposed on a side opposite to two-dimensional material layer 1 with respect to thermoelectric conversion material layer 5. Third electrode portion 2c and second electrode portion 2b are disposed to sandwich at least a part of each of semiconductor layer 4, two-dimensional material layer 1, insulating film 3, and thermoelectric conversion material layer 5.

Third electrode portion 2c is in contact with thermoelectric conversion material layer 5. Third electrode portion 2c is in contact with, for example, each of fourth portion 5a, fifth portion 5b, and sixth portion Sc of thermoelectric conversion material layer 5. Third electrode portion 2c may be in contact with only one of fourth portion 5a, fifth portion 5b, and sixth portion 5c of thermoelectric conversion material layer 5.

A material constituting third electrode portion 2c may be any material having conductivity, and includes, for example, at least one selected from the group consisting of gold (Au), silver (Ag), copper (Cu), aluminum (Al), nickel (Ni), chromium (Cr), and palladium (Pd). Further, an adhesion layer without being illustrated may be formed between third electrode portion 2c and thermoelectric conversion material layer 5. The adhesion layer enhances adhesion between third electrode portion 2c and thermoelectric conversion material layer 5. A material constituting the adhesion layer is not particularly limited, but may contain, for example, at least one of chromium (Cr) and titanium (Ti).

Third electrode portion 2c is electrically connected to thermoelectric conversion material layer 5. In an electromagnetic wave detector 117, voltages can be applied between third electrode portion 2c and second electrode portion 2b and between third electrode portion 2c and second electrode portion 2b. As illustrated in FIG. 30, third electrode portion 2c and first electrode portion 2a are connected in parallel to a power supply PW, for example. In this case, the voltage applied between third electrode portion 2c and second electrode portion 2b is equal to, for example, the voltage applied between third electrode portion 2c and second electrode portion 2b.

Note that third electrode portion 2c and first electrode portion 2a may be connected to different power supplies. In this case, the voltage applied between third electrode portion 2c and second electrode portion 2b can be adjusted independently of the voltage applied between third electrode portion 2c and second electrode portion 2b. The voltage applied between third electrode portion 2c and second electrode portion 2b may be different from the voltage applied between third electrode portion 2c and second electrode portion 2b.

In a case where the electromagnetic wave is incident on thermoelectric conversion material layer 5 from third electrode portion 2c side, third electrode portion 2c preferably exhibits high transmittance at the wavelength of the electromagnetic wave detected by the electromagnetic wave detector.

Note that third electrode portion 2c can be disposed at any place as long as third electrode portion 2c is electrically connected to thermoelectric conversion material layer 5. Preferably, third electrode portion 2c is disposed to make a direction where a voltage is applied from third electrode portion 2c to thermoelectric conversion material layer 5 perpendicular to the extending direction of two-dimensional material layer 1.

A configuration of the electromagnetic wave detector according to the present embodiment can also be applied to other embodiments.

### <Operation and Effect>

Electromagnetic wave detector 115 includes third electrode portion 2c electrically connected to thermoelectric conversion material layer S. Therefore, in an electromagnetic wave detector 116, the voltage can be applied between third electrode portion 2c and second electrode portion 2b, and the potential difference generated in thermoelectric conversion material layer 5 can be adjusted.

Further, in a case where the voltage applied between third electrode portion 2c and second electrode portion 2b is adjusted independently of the voltage applied between third electrode portion 2c and second electrode portion 2b, the potential difference generated in thermoelectric conversion material layer 5 due to the thermoelectric power generation effect when the electromagnetic wave is irradiated to thermoelectric conversion material layer 5 can be adjusted based on the voltage applied between third electrode portion 2c and second electrode portion 2b. In this case, when thermoelectric conversion material layer 5 is irradiated with the electromagnetic wave, the energy barrier between two-dimensional material layer 1 and semiconductor layer 4 can be efficiently lowered, and the sensitivity of the electromagnetic wave detector is improved.

### Thirteenth Embodiment

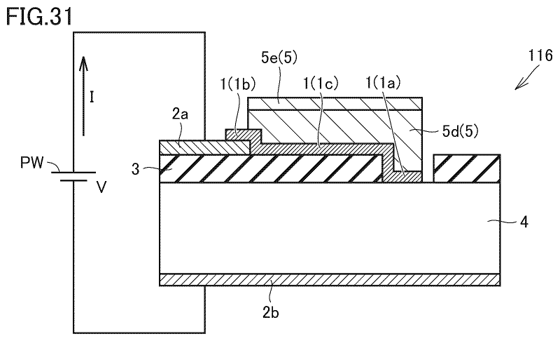

FIG. 31 is a schematic cross-sectional view of the electromagnetic wave detector according to the thirteenth embodiment. Electromagnetic wave detector 116 illustrated in FIG. 31 basically has a similar configuration to that of electromagnetic wave detector 100 illustrated in FIGS. 1 and 2 and can obtain similar effects, but is different from electromagnetic wave detector 100 in that thermoelectric conversion material layer 5 includes a first thermoelectric conversion material portion 5d and a second thermoelectric conversion material portion 5e. Hereinafter, differences between electromagnetic wave detector 116 and electromagnetic wave detector 100 will be mainly described.

First thermoelectric conversion material portion 5d contains a first thermoelectric conversion material. Second thermoelectric conversion material portion 5e contains a second thermoelectric conversion material different from the first thermoelectric conversion material.

In electromagnetic wave detector 117, only first thermoelectric conversion material portion 5d of thermoelectric conversion material layer 5 is in contact with two-dimensional material layer 1. Second thermoelectric conversion material portion 5e is not in contact with two-dimensional material layer 1. Second thermoelectric conversion material portion 5e is in contact with first thermoelectric conversion material portion 5d. Second thermoelectric conversion material portion 5e is disposed on a side opposite to two-dimensional material layer 1 with respect to first thermoelectric conversion material portion 5d. Second thermoelectric conversion material portion 5c is electrically connected to two-dimensional material layer 1 via first thermoelectric conversion material portion 5d.

A material constituting each of first thermoelectric conversion material portion 5d and second thermoelectric conversion material portion 5e may be any thermoelectric conversion material in which a potential difference is generated due to a temperature difference, but preferably, absorption wavelengths of the electromagnetic waves are different from each other.

Each of first thermoelectric conversion material portion 5d and second thermoelectric conversion material portion 5e is disposed on, for example, each of first portion 1a, second portion 1b, and third portion 1c of two-dimensional material layer 1, but is not limited thereto.

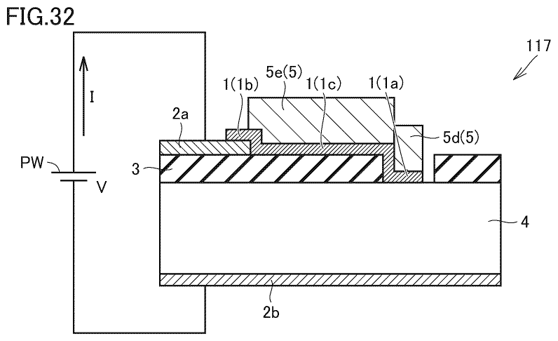

FIG. 32 is a schematic cross-sectional view illustrating electromagnetic wave detector 117 according to a variation of the thirteenth embodiment. In electromagnetic wave detector 117 illustrated in FIG. 32, each of first thermoelectric conversion material portion 5d and second thermoelectric conversion material portion 5e in thermoelectric conversion material layer 5 is in contact with two-dimensional material layer 1.

First thermoelectric conversion material portion 5d is in contact with first portion 1a of two-dimensional material layer 1. In plan view, first thermoelectric conversion material portion 5d is disposed to overlap with first portion 1a of two-dimensional material layer 1. Second thermoelectric conversion material portion 5e is in contact with each of second portion 1b and third portion 1c of two-dimensional material layer 1. In plan view, second thermoelectric conversion material portion 5e is disposed to overlap with second portion 1b and third portion 1c of two-dimensional material layer 1.

Preferably, a Seebeck coefficient of the first thermoelectric conversion material is different from a Seebeck coefficient of the second thermoelectric conversion material. More preferably, the Seebeck coefficient of each of the first thermoelectric conversion material and the second thermoelectric conversion material is designed to make the Fermi level in each of first portion 1a, second portion 1b, and third portion 1c of two-dimensional material layer 1 optimal. For example, the Seebeck coefficient of the first thermoelectric conversion material constituting first thermoelectric conversion material portion 5d in contact with first portion 1a is set higher than the Seebeck coefficient of the second thermoelectric conversion material constituting second thermoelectric conversion material portion 5e in contact with each of second portion 1b and third portion 1c.

### <Operation and Effect>

In electromagnetic wave detector 116 and electromagnetic wave detector 117, since thermoelectric conversion material layer 5 contains first thermoelectric conversion material portion 5d and second thermoelectric conversion material portion 5e containing the thermoelectric conversion materials different from each other, the thermoelectric power generation effect and the optical gate effect can be adjusted by appropriately adjusting a combination of the first thermoelectric conversion material and the second thermoelectric conversion material.

In electromagnetic wave detector 116, in a case where an electromagnetic wave absorption wavelength of the first thermoelectric conversion material is different from an electromagnetic wave absorption wavelength of the second thermoelectric conversion material, it is possible to detect a broadband wavelength as compared with a case where the electromagnetic wave absorption wavelength of the first thermoelectric conversion material is equal to the electromagnetic wave absorption wavelength of the second thermoelectric conversion material.

In electromagnetic wave detector 117, in a case where the electromagnetic wave absorption wavelength of the first thermoelectric conversion material is different from the electromagnetic wave absorption wavelength of the second thermoelectric conversion material, the Fermi level in each of first portion 1a, second portion 1b, and third portion 1c of two-dimensional material layer 1 can be designed to be optimal. In this case, performance of electromagnetic wave detector 117 is improved.

### Fourteenth Embodiment

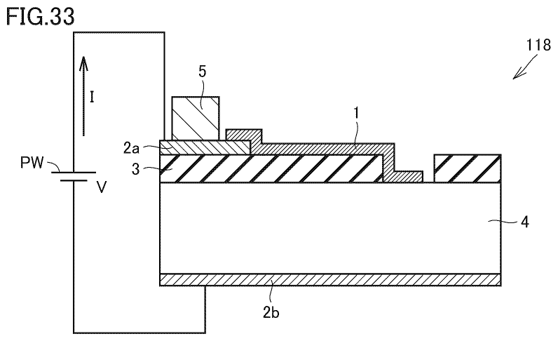

FIG. 33 is the cross-sectional view of the electromagnetic wave detector according to the fourteenth embodiment. An electromagnetic wave detector 118 illustrated in FIG. 33 basically has a similar configuration to that of electromagnetic wave detector 100 illustrated in FIGS. 1 and 2 and can obtain similar effects, but is different from electromagnetic wave detector 100 in that thermoelectric conversion material layer 5 is spaced apart from two-dimensional material layer 1 and disposed to overlap with only first electrode portion 2a of two-dimensional material layer 1 and first electrode portion 2a.

In electromagnetic wave detector 118, thermoelectric conversion material layer 5 is disposed on first electrode portion 2a. Thermoelectric conversion material layer 5 is in contact with first electrode portion 2a. First electrode portion 2a and second electrode portion 2b are connected to the power supply circuit.

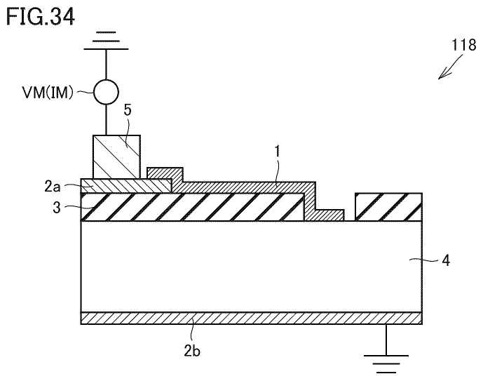

FIG. 34 is a schematic cross-sectional view illustrating a variation of electromagnetic wave detector 118 according to the fourteenth embodiment. As illustrated in FIG. 34, thermoelectric conversion material layer 5 of electromagnetic wave detector 118 may be connected to voltmeter VM or ammeter IM, and second electrode portion 2b may be grounded.

### <Operation and Effect>

In electromagnetic wave detector 100, since thermoelectric conversion material layer 5 is in contact with two-dimensional material layer 1, the Fermi level of two-dimensional material layer 1 significantly changes, and characteristics of electromagnetic wave detector 100 greatly change in a case where a significantly large potential difference is generated in thermoelectric conversion material layer S. Therefore, the detection sensitivity of electromagnetic wave detector 100 may decrease. Meanwhile, in electromagnetic wave detector 118, since thermoelectric conversion material layer 5 is spaced apart from two-dimensional material layer 1 and disposed to overlap with only first electrode portion 2a of two-dimensional material layer 1 and first electrode portion 2a, the electric field caused by the potential difference generated in thermoelectric conversion material layer 5 is less likely to reach two-dimensional material layer 1 as compared with electromagnetic wave detector 100. In other words, in electromagnetic wave detector 118, the optical gate effect due to the thermoelectric power generation effect is less likely to be obtained as compared with electromagnetic wave detector 100. Therefore, in electromagnetic wave detector 118, even if the significantly large potential difference is generated in thermoelectric conversion material layer 5, a decrease in detection sensitivity can be suppressed.

Here, the configuration of the electromagnetic wave detector according to the present embodiment can also be applied to other embodiments.

### Fifteenth Embodiment

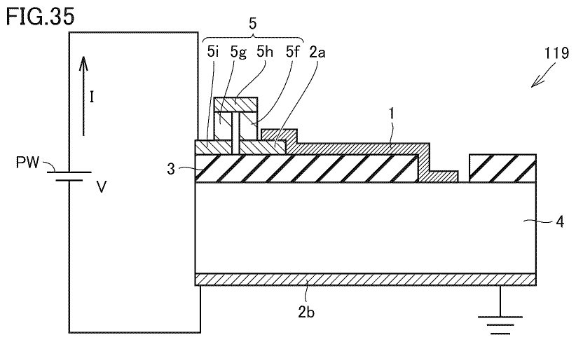

FIG. 35 is the cross-sectional view of the electromagnetic wave detector according to the fifteenth embodiment. An electromagnetic wave detector 119 illustrated in FIG. 35 basically has a similar configuration to that of electromagnetic wave detector 118 illustrated in FIGS. 33 and 34 and can obtain similar effects, but is different from electromagnetic wave detector 118 in that thermoelectric conversion material layer 5 includes a n-type structure portion in which a plurality of the thermoelectric conversion material portions having polarities different from each other are connected in series via conductive portions. Hereinafter, differences between electromagnetic wave detector 119 and electromagnetic wave detector 118 will be mainly described.

As illustrated in FIG. 35, thermoelectric conversion material layer 5 includes a third thermoelectric conversion material portion Sf, a fourth thermoelectric conversion material portion 5g, a first conductive portion 5h, and a second conductive portion Si. One end (an upper end) of each of third thermoelectric conversion material portion 5f and fourth thermoelectric conversion material portion 5g is connected in series via first conductive portion Sh. Another end (a lower end) of third thermoelectric conversion material portion 5f is connected to first electrode portion 2a. Another end (a lower end) of fourth thermoelectric conversion material portion 5g is connected to second conductive portion 5i.

Third thermoelectric conversion material portion 5f and fourth thermoelectric conversion material portion Sg have different polarities. A material constituting first conductive portion 5h and second conductive portion 5i may be any material having conductivity, and includes, for example, at least one selected from the group consisting of gold (Au), silver (Ag), copper (Cu), aluminum (Al), nickel (Ni), chromium (Cr), and palladium (Pd).

As illustrated in FIG. 35, in electromagnetic wave detector 119, two-dimensional material layer 1, first electrode portion 2a, third thermoelectric conversion material portion 5f, first conductive portion 5h, fourth thermoelectric conversion material portion 5g, and second conductive portion 5i are sequentially connected in series. In electromagnetic wave detector 119, bias voltage V (or the bias current) is applied between second conductive portion Si of thermoelectric conversion material layer 5 and second electrode portion 2b.

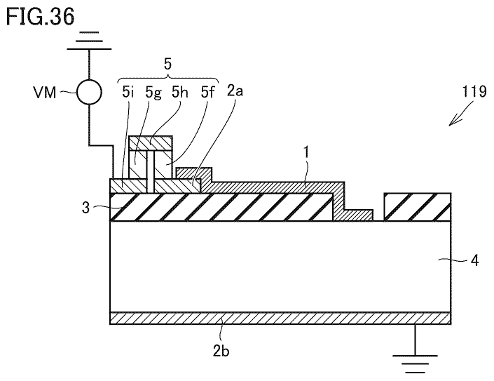

FIG. 36 is a schematic cross-sectional view illustrating a first variation of electromagnetic wave detector 119 according to the fifteenth embodiment. As illustrated in FIG. 36, second conductive portion Si of thermoelectric conversion material layer 5 of electromagnetic wave detector 119 may be connected to voltmeter VM or ammeter IM, and second electrode portion 2b may be grounded.

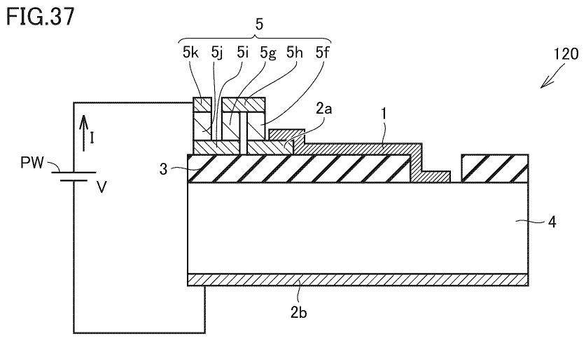

FIG. 37 is a schematic cross-sectional view illustrating an electromagnetic wave detector 120 according to a second variation of the fifteenth embodiment. Electromagnetic wave detector 120 illustrated in FIG. 37 basically has a similar configuration to that of electromagnetic wave detector 119 illustrated in FIGS. 35 and 36, and can obtain similar effects, but is different from electromagnetic wave detector 119 in that thermoelectric conversion material layer 5 further includes a fifth thermoelectric conversion material portion 5j and a third conductive portion 5k. A polarity of fifth thermoelectric conversion material portion 5j is different from a polarity of fourth thermoelectric conversion material portion 5g. One end (a lower end) of fifth thermoelectric conversion material portion 5j is connected to second conductive portion 5i. Another end (an upper end) of fifth thermoelectric conversion material portion 5j is connected to third conductive portion 5k.

As illustrated in FIG. 37, in electromagnetic wave detector 120, two-dimensional material layer 1, first electrode portion 2a, third thermoelectric conversion material portion 5f, first conductive portion 5h, fourth thermoelectric conversion material portion 5g, second conductive portion 5i, fifth thermoelectric conversion material portion 5j, and third conductive portion 5k are sequentially connected in series. In electromagnetic wave detector 19, the bias voltage V (or the bias current) is applied between third conductive portion 5k of thermoelectric conversion material layer 5 and second electrode portion 2b.

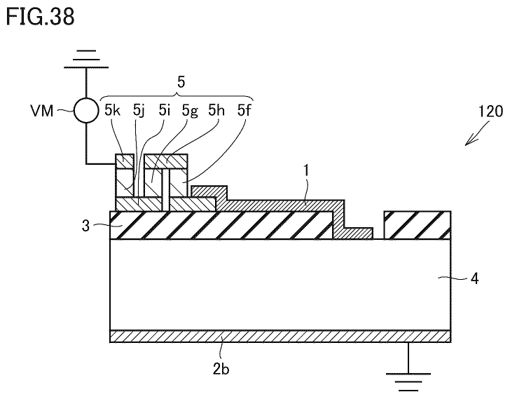

FIG. 38 is a schematic cross-sectional view illustrating a third variation of electromagnetic wave detector 120. As illustrated in FIG. 38, third conductive portion 5k of thermoelectric conversion material layer 5 of electromagnetic wave detector 120 may be connected to voltmeter VM or ammeter IM, and second electrode portion 2b may be grounded.

Note that, in the electromagnetic wave detector according to the present embodiment, in the π-type structure portion of thermoelectric conversion material layer 5, four or more thermoelectric conversion material portions with polarities different from each other may be connected in series via a plurality of the conductive portions.

Further, also in the electromagnetic wave detector according to the present embodiment, thermoelectric conversion material layer 5 may be in contact with at least a part of two-dimensional material layer 1.

### <Operation and Effect>

In electromagnetic wave detector 19 and electromagnetic wave detector 120, since thermoelectric conversion material layer 5 has the π-type structure portion, a potential difference generated in third thermoelectric conversion material portion 5f and a potential difference generated in fourth thermoelectric conversion material portion 5g are added up and increased, and detection sensitivity of each of the electromagnetic wave detectors is improved.

Here, the configuration of the electromagnetic wave detector according to the present embodiment can also be applied to other embodiments.

### Sixteenth Embodiment

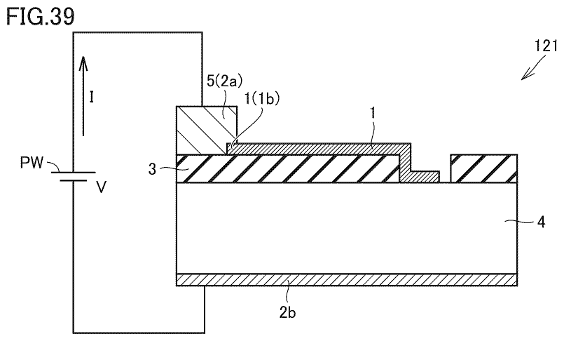

FIG. 39 is a schematic cross-sectional view of the electromagnetic wave detector according to the sixteenth embodiment. An electromagnetic wave detector 121 illustrated in FIG. 39 basically has a similar configuration to that of electromagnetic wave detector 100 illustrated in FIGS. 1 and 2 and can obtain similar effects, but is different from electromagnetic wave detector 100) in that thermoelectric conversion material layer 5 is integrally configured with first electrode portion 2a. Hereinafter, differences between electromagnetic wave detector 121 and electromagnetic wave detector 100 will be mainly described.

In electromagnetic wave detector 119 illustrated in FIG. 39, thermoelectric conversion material layer 5 is configured as the same member as first electrode portion 2a. Thermoelectric conversion material layer 5 is disposed on insulating film 3 and in contact with only second portion 1b of two-dimensional material layer 1.

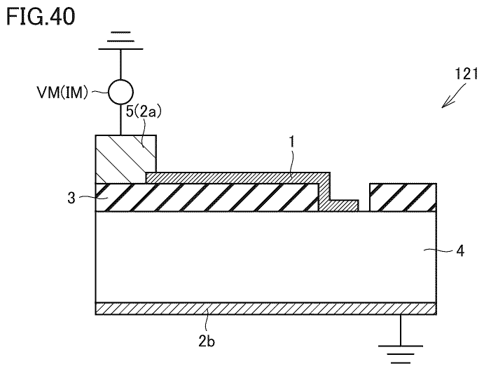

FIG. 40 is a schematic cross-sectional view illustrating a variation of electromagnetic wave detector 121 according to the sixteenth embodiment. As illustrated in FIG. 40, thermoelectric conversion material layer 5 of electromagnetic wave detector 121 may be connected to voltmeter VM or ammeter IM, and second electrode portion 2b may be grounded.

### <Operation and Effect>

In electromagnetic wave detector 121, since thermoelectric conversion material layer 5 is configured as the same member as first electrode portion 2a, the number of parts and the number of manufacturing steps can be reduced as compared with a case where thermoelectric conversion material layer 5 is configured as a separate member from first electrode portion 2a.

### Seventeenth Embodiment

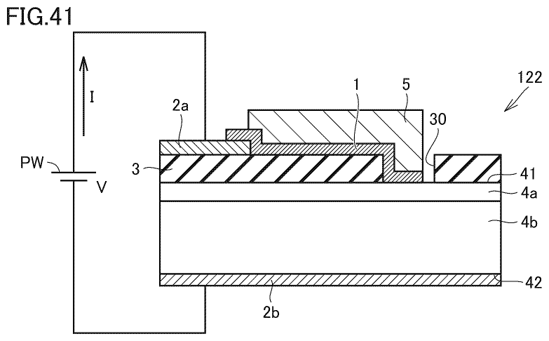

FIG. 41 is a schematic cross-sectional view of the electromagnetic wave detector according to the seventeenth embodiment.

An electromagnetic wave detector 122 illustrated in FIG. 41 basically has a similar configuration to that of electromagnetic wave detector 100 illustrated in FIGS. 1 and 2 and can obtain similar effects, but a configuration of semiconductor layer 4 is different from that of the electromagnetic wave detector illustrated in FIGS. 1 and 2. In other words, the electromagnetic wave detector illustrated in FIG. 41 is different from electromagnetic wave detector 100 in that semiconductor layer 4 includes a semiconductor layer 4a of a first conductive type (a first semiconductor portion) and a semiconductor layer 4b of a second conductive type (a second semiconductor portion). Hereinafter, differences between electromagnetic wave detector 122 and electromagnetic wave detector 100 will be mainly described.

As illustrated in FIG. 41, semiconductor layer 4 includes, for example, semiconductor layer 4a and semiconductor layer 4b. Semiconductor layer 4a has first surface 41, and semiconductor layer 4b has second surface 42. Semiconductor layer 4a is exposed at opening 30 of insulating film 3, and electrically connected to first electrode portion 2a via two-dimensional material layer 1. Semiconductor layer 4a is in contact with, for example, two-dimensional material layer 1 and insulating film 3. Semiconductor layer 4b is disposed on a side opposite to two-dimensional material layer 1 with respect to semiconductor layer 4a, for example, and electrically connected to second electrode portion 2b.

The conductive type of semiconductor layer 4a is different from the conductive type of semiconductor layer 4b. For example, the conductive type of semiconductor layer 4a is the n-type, and the conductive type of semiconductor layer 4b is the p-type. Accordingly, semiconductor layer 4a and semiconductor layer 4b constitute a diode.

Semiconductor layer 4a and semiconductor layer 4b may constitute a photodiode sensitive to a wavelength different from that of thermoelectric conversion material layer 5.

Note that semiconductor layer 4a and semiconductor layer 4b are laminated in FIG. 41, but are not limited thereto. Further, semiconductor layer 4 may include three or more semiconductor layers.

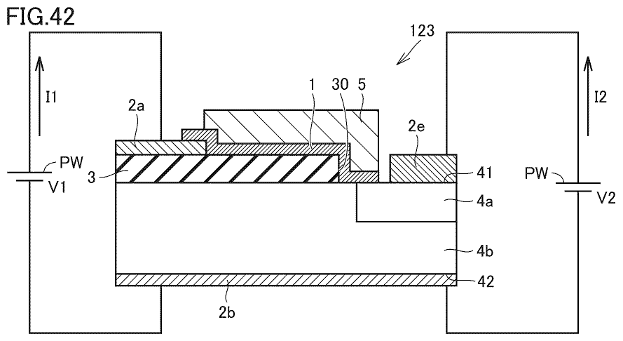

FIG. 42 is a schematic cross-sectional view illustrating a variation of the electromagnetic wave detector according to the seventeenth embodiment. An electromagnetic wave detector 123 illustrated in FIG. 42 basically has a similar configuration to that of electromagnetic wave detector 122 illustrated in FIG. 41 and can obtain similar effects, but is different from electromagnetic wave detector 122 in that electromagnetic wave detector 123 further includes a fourth electrode portion 2e electrically connected to semiconductor layer 4a (the first semiconductor portion) in addition to second electrode portion 2b electrically connected to semiconductor layer 4b (the second semiconductor portion).

Two-dimensional material layer 1 is electrically connected to each of semiconductor layer 4a and semiconductor layer 4b. An interface between semiconductor layer 4a and semiconductor layer 4b is disposed in opening 30 of insulating film 3. Semiconductor layer 4a is in contact with each of two-dimensional material layer 1 and fourth electrode portion 2e, for example. For example, semiconductor layer 4b is in contact with two-dimensional material layer 1 and insulating film 3 in addition to second electrode portion 2b.

As illustrated in FIG. 42, a voltage V2 is applied between second electrode portion 2b and fourth electrode portion 2e. Preferably, voltage V2 is set to be a reverse bias with respect to pi junction between semiconductor layer 4a and semiconductor layer 4b.

Here, the configuration of the electromagnetic wave detector according to the present embodiment can also be applied to other embodiments.

### <Operation and Effect>

In electromagnetic wave detector 122 and electromagnetic wave detector 123, the dark current can be reduced by forming the pn junction by semiconductor layer 4a and semiconductor layer 4b. Further, in a case where semiconductor layer 4a and semiconductor layer 4b constitute the photodiode sensitive to the wavelength different from that of thermoelectric conversion material layer 5, the broadband wavelength can be detected with thermoelectric conversion material layer 5 and the above photodiode.

### Eighteenth Embodiment

The electromagnetic wave detector according to the present embodiment is different from electromagnetic wave detector 100 illustrated in FIGS. 1 and 2 in that two-dimensional material layer 1 includes a turbostratic structure portion.

In the electromagnetic wave detector according to the present embodiment, at least a part of two-dimensional material layer 1 has a turbostratic structure. Here, the turbostratic structure is a region in which a plurality of graphene layers are laminated, and means a structure in which the graphene layers are laminated in a state where lattices of the laminated graphene layers are mismatched. Note that the entire two-dimensional material layer 1 may have the turbostratic structure, or only a portion acting as a channel may have the turbostratic structure. A portion of two-dimensional material layer 1 in contact with insulating film 3 may have the turbostratic structure.

Any method can be used as a method for forming the turbostratic structure portion. For example, the turbostratic structure portion can be formed by transferring the single-layer graphene formed by the CVD method multiple times and laminating the multilayer graphene. Further, the turbostratic structure portion can also be formed by cause the graphene to grow on the graphene by the CVD method by using ethanol, methane, or the like as a carbon source. Here, a normal multilayer graphene is called A-B lamination, and is laminated in a state where the lattices of the laminated graphene layers are matched. However, the graphene produced by the CVD method is polycrystalline, and in a case where the graphene is further transferred on the graphene multiple times, or in a case where the graphene is laminated on base graphene by the CVD method, the turbostratic structure in which the lattices of the laminated graphene layers are mismatched is obtained. The graphene having the turbostratic structure has little influence of interlayer interaction and has properties equivalent to those of the single-layer graphene.

Here, the configuration of the electromagnetic wave detector according to the present embodiment can also be applied to other embodiments.

### <Operation and Effect>

In the electromagnetic wave detector according to the present embodiment, two-dimensional material layer 1 includes the turbostratic structure. In this case, the mobility of the carriers in two-dimensional material layer 1 can be improved. As a result, the sensitivity of the electromagnetic wave detector can be improved.

Specifically, the mobility of the carriers in two-dimensional material layer 1 decreases if the graphene is affected by the carrier scattering in insulating film 3 in contact with two-dimensional material layer 1 as a base. Meanwhile, in a case where two-dimensional material layer 1 includes the turbostratic structure portion, in the turbostratic structure portion, the graphene in contact with the base is affected by the carrier scattering. However, upper graphene laminated on the graphene in the turbostratic structure is less likely to be affected by the carrier scattering from the base. Further, the graphene having the turbostratic structure has improved conductivity because of little interaction between adjacent graphene layers. As described above, the mobility of the carriers is improved in the graphene having the turbostratic structure, and electromagnetic wave detector 100 including the graphene having the turbostratic structure has improved sensitivity to the electromagnetic wave.

### Nineteenth Embodiment

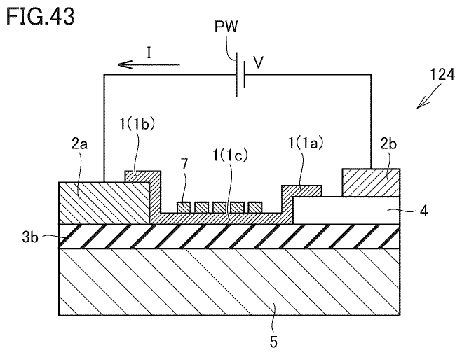

FIG. 43 is a schematic cross-sectional view of the electromagnetic wave detector according to the nineteenth embodiment. An electromagnetic wave detector 124 illustrated in FIG. 43 basically has a similar configuration to that of electromagnetic wave detector 100 illustrated in FIGS. 1 and 2, and can obtain similar effects, but is different from electromagnetic wave detector 100 in that electromagnetic wave detector 124 further includes one or more conductors 7, that are disposed in contact with two-dimensional material layer 1. Hereinafter, differences between electromagnetic wave detector 124 and electromagnetic wave detector 100 will be mainly described.

As illustrated in FIG. 43, electromagnetic wave detector 124 includes, for example, a plurality of conductors 7. Each of the plurality of conductors 7 is in contact with two-dimensional material layer 1. Each of the plurality of conductors 7 is in contact with, for example, third portion 1c of two-dimensional material layer 1. Each of the plurality of conductors 7 is spaced apart from each other on an upper surface of third portion 1c of two-dimensional material layer 1.

Each of the plurality of conductors 7 is not connected to the power supply circuit or the like and acts as a floating electrode.

A material constituting each of conductors 7 may be any material having conductivity, and includes, for example, at least one selected from the group consisting of gold (Au), silver (Ag), copper (Cu), aluminum (Al), nickel (Ni), chromium (Cr), and palladium (Pd). Preferably, the material constituting each of conductors 7 is a material in which the surface plasmon resonance occurs.

The plurality of conductors 7 has, for example, a one-dimensional periodic structure or a two-dimensional periodic structure. The plurality of conductors 7 each having the one-dimensional periodic structure is periodically spaced apart from each other along, for example, a horizontal direction on a paper of FIG. 43 or a depth direction of the paper. Each of the plurality of conductors 7 having the two-dimensional periodic structure is arranged at a position corresponding to a lattice point such as a square lattice or a triangular lattice in plan view, for example. The arrangement of the plurality of conductors 7 in plan view is not limited to the above-described arrangement having periodic symmetry, and may be an arrangement having asymmetry in plan view.

In plan view, a planar shape of each of conductors 7 may be any shape such as a circular shape, a triangular shape, a quadrangular shape, a polygonal shape, or an elliptical shape.

A method for forming conductors 7 is not particularly limited, but for example, may be formed in a similar manner to first electrode portion 2a.

Further, in the above electromagnetic wave detector, conductors 7 may be disposed under two-dimensional material layer 1. Even with such configuration, similar effects to those of the electromagnetic wave detector illustrated in FIG. 43 can be obtained. Moreover, in this case, since two-dimensional material layer 1 is not damaged during formation of conductors 7, the decrease in the mobility of the carriers in two-dimensional material layer 1 can be suppressed.

Further, an uneven portion may be formed on two-dimensional material layer 1, in this case, the uneven portion of two-dimensional material layer 1 may have a periodic structure or an asymmetric structure similar to those of the plurality of conductors 7 described above. In this case, similar effects to a case of forming the plurality of conductors 7 can be obtained.

Here, the configuration of the electromagnetic wave detector according to the present embodiment can also be applied to other embodiments.

### <Operation and Effect>

Electromagnetic wave detector 124 includes one or more conductors 7 in contact with two-dimensional material layer 1. Therefore, in electromagnetic wave detector 124, surface carriers generated by the irradiation of the electromagnetic wave in thermoelectric conversion material layer 5 can move back and forth between two-dimensional material layer 1 and each of conductors 7 and between the plurality of conductors 7, and a lifetime of the photocarriers in two-dimensional material layer 1 becomes long, and detection sensitivity of the electromagnetic wave detector becomes high.

Further, if the material constituting conductors 7 is a material that causes the surface plasmon resonance and the plurality of conductors 7 each have the one-dimensional periodic structure, polarization dependency occurs in conductors 7 due to the irradiated electromagnetic wave. In such electromagnetic wave detector 124, since only an electromagnetic wave of a specific polarization is irradiated to semiconductor layer 4, only the specific polarization can be detected.

Further, if the material constituting conductors 7 is the material that causes the surface plasmon resonance and the plurality of conductors 7 each have the two-dimensional periodic structure, the plurality of conductors 7 can cause the electromagnetic wave having the specific wavelength to resonate, and thus only the electromagnetic wave having the specific wavelength can be detected.

Further, also in a case where the plurality of conductors 7 are disposed asymmetrically in plan view, similarly to a case where the plurality of conductors 7 each have the one-dimensional periodic structure, the polarization dependency occurs in conductors 7 for the irradiated electromagnetic wave, and only the specific polarization can be detected.

### Twentieth Embodiment

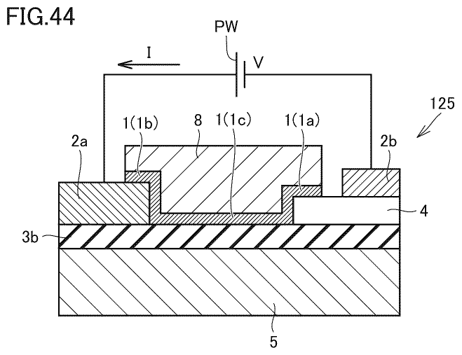

FIG. 44 is a schematic cross-sectional view of the electromagnetic wave detector according to the twentieth embodiment. An electromagnetic wave detector 125 illustrated in FIG. 44 basically has a similar configuration to that of electromagnetic wave detector 100 illustrated in FIGS. 1 and 2 and can obtain similar effects, but is different from electromagnetic wave detector 100 in that electromagnetic wave detector 125 further includes one or more contact layers 8 in contact with two-dimensional material layer 1. Hereinafter, differences between electromagnetic wave detector 125 and electromagnetic wave detector 100 will be mainly described. As illustrated in FIG. 44, contact layers 8 are in contact with, for example, each of first portion 1a, second portion 1b, and third portion 1c of two-dimensional material layer 1. Note that contact layers 8 may be in contact with at least one of first portion 1a, second portion 1b, and third portion 1c of two-dimensional material layer 1. Contact layers 8 may be formed only on one of first electrode portion 2a side and semiconductor layer 4 side on the upper surface of two-dimensional material layer 1. In other words, contact layers 8 may be in contact with only first portion 1a and second portion 1b.

A material constituting contact layers 8 is a material capable of supplying the positive holes or the electrons to two-dimensional material layer 1. The material constituting contact layers 8 is, for example, a composition called positive photoresist that contains a photosensitizer having a quinone diazite group and a novolak resin. Further, the material constituting contact layers 8 may be, for example, any material having a polar group. Examples of such material include a material having an electron-withdrawing group or a material having an electron-donating group. A material having the electron-withdrawing group has an effect of reducing an electron density of two-dimensional material layer 1. A material having the electron-donating group has an effect of increasing the electron density of two-dimensional material layer 1. Examples of the material having the electron-withdrawing group include a material having at least one selected from the group consisting of halogen, nitrile, a carboxyl group, and a carbonyl group. Further, examples of the material having the electron-donating group include a material having at least one selected from the group consisting of an alkyl group, an alcohol, an amino group, and a hydroxyl group.

The material constituting contact layers 8 may be other than the above materials, and may be, for example, a material in which a charge bias occurs throughout the molecules due to the polar group. The material constituting contact layers 8 may be an organic substance, metal, a semiconductor, an insulator, a two-dimensional material, or a mixture of any of these materials, and may be any material in which the charge bias occurs in the molecules to generate polarity. Here, in a case where the material constituting contact layers 8 is an inorganic substance, the conductive type in which two-dimensional material layer 1 is doped is preferably the p-type if a work function of each of contact layers 8 is larger than a work function of two-dimensional material layer 1, and is preferably the n-type if the work function of each of contact layers 8 is smaller than the work function of two-dimensional material layer 1.

In a case where contact layers 8 contain the organic substance, the organic substance which is the material constituting contact layers 8 does not have a clear work function. Therefore, whether or not two-dimensional material layer 1 is subjected to n-type doping or p-type doping is preferably determined based on the polarity of molecules of the organic substance used for contact layers 8 to determine the polar group of the material of contact layers 8.

For example, in a case where the composition called the positive photoresist that contains the photosensitizer having the quinone diazite group and the novolak resin is used as contact layers 8, a region where the resist is formed in two-dimensional material layer 1 by a photolithography step is a p-type two-dimensional material layer region. Accordingly, this eliminates a need for a process of forming the mask in contact with the surfaces of two-dimensional material layer 1. As a result, it is possible to reduce the process damage to two-dimensional material layer 1 and simplify the process.

Electromagnetic wave detector 125 may include the plurality of contact layers 8. The number of contact layers 8 may be greater than or equal to three, and may be any number. The material constituting each of the plurality of contact layers 8 may be the same material or different materials from each other. At least one contact layer 8 of the plurality of contact layers 8 may be disposed on third portion 1c of two-dimensional material layer 1 located between first electrode portion 2a and semiconductor layer 4.

Here, the configuration of the electromagnetic wave detector according to the present embodiment can also be applied to other embodiments.

### <Operation and Effect>

In electromagnetic wave detector 125, since contact layers 8 in contact with two-dimensional material layer 1 supply the positive holes or the electrons to two-dimensional material layer 1, carrier doping of two-dimensional material layer 1 can be controlled without considering influence of the carrier doping from first electrode portion 2a and semiconductor layer 4 to two-dimensional material layer 1. As a result, performance of electromagnetic wave detector 125 is improved.

Further, in electromagnetic wave detector 125, for example, by using the material having the electron-withdrawing group or the material having the electron-donating group as the material of contact layers 8, a state (the conductive type) of two-dimensional material layer 1 can be intentionally made the n-type or the p-type. In this case, the carrier doping of two-dimensional material layer 1 can be controlled without considering the influence of the carrier doping from the electric fields of first electrode portion 2a, semiconductor layer 4, and thermoelectric conversion material layer 5. As a result, performance of electromagnetic wave detector 125 is improved.

Further, in a case where contact layers 8 are formed only on one of first electrode portion 2a side and semiconductor layer 4 side on the upper surface of two-dimensional material layer 1, a gradient of a charge density is formed in two-dimensional material layer 1. As a result, the mobility of the carriers in two-dimensional material layer 1 is improved, and detection sensitivity of electromagnetic wave detector 125 is increased.

In electromagnetic wave detector 125, a thickness of each of contact layers 8 is preferably sufficiently thin to enable the photoelectric conversion in a case where two-dimensional material layer 1 is irradiated with the electromagnetic wave. Meanwhile, the thickness of each of contact layers 8 is preferably such thickness that the carriers are doped from contact layers 8 to two-dimensional material layer 1.

Contact layers 8 may have any configuration as long as the carriers such as the molecules or the electrons can be doped in two-dimensional material layer 1.

Further, electromagnetic wave detector 125 includes contact layers 8 in a solid form, but also in the electromagnetic wave detector according to another embodiment without contact layers 8, the carrier doping of two-dimensional material layer 1 can be controlled by immersing two-dimensional material layer 1 in a solution and supplying the carriers to two-dimensional material layer 1 at a molecular level.

Further, the material constituting contact layers 8 may be a material that causes polarity conversion in addition to the materials described above. In this case, if contact layers 8 are subjected to the polarity conversion, the electrons or the positive holes generated during the conversion are supplied to two-dimensional material layer 1. Therefore, the doping of the electrons or the positive holes occurs in a portion of two-dimensional material layer 1 in contact with contact layers 8. Therefore, even if contact layers 8 are removed after the doping, the portion of two-dimensional material layer 1 in contact with contact layers 8 remains doped with the electrons or the positive holes. Accordingly, in a case where the material constituting contact layers 8 is the material that causes the polarity conversion, contact layers 8 may be removed from two-dimensional material layer 1 after a certain period of time has elapsed since electromagnetic wave detector 125 was manufactured. In this case, since an opening area of two-dimensional material layer 1 is increased as compared with a case where contact layers 8 are present, the detection sensitivity of the electromagnetic wave detector is improved. Here, the polarity conversion is a phenomenon in which the polar group is chemically converted, and means, for example, a phenomenon in which the electron-withdrawing group is changed to the electron-donating group, the electron-donating group is changed to the electron-withdrawing group, the polar group is changed to the nonpolar group, or the nonpolar group is changed to the polar group.

Further, contact layers 8 may be formed by the material that causes the polarity conversion by electromagnetic wave irradiation. In this case, by selecting the material that causes the polarity conversion at the specific wavelength of the electromagnetic wave as the material of contact layers 8, it is possible to cause the polarity conversion in contact layers 8 only during the electromagnetic wave irradiation at the specific wavelength of the electromagnetic wave, and perform the doping to two-dimensional material layer 1. As a result, the photocurrent flowing into two-dimensional material layer 1 can be increased.

Further, a material that causes an oxidation-reduction reaction by the electromagnetic wave irradiation may be used as the material of contact layers 8. In this case, two-dimensional material layer 1 can be doped with the electrons or the positive holes generated during the oxidation-reduction reaction.

### Twenty-First Embodiment

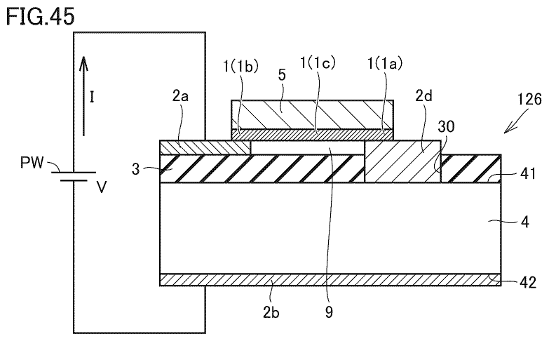

FIG. 45 is a schematic cross-sectional view of the electromagnetic wave detector according to the twenty-first embodiment. An electromagnetic wave detector 126 illustrated in FIG. 45 basically has a similar configuration to that of electromagnetic wave detector 100 illustrated in FIGS. 1 and 2 and can obtain similar effects, but is different from electromagnetic wave detector 100 in that a void 9 is formed around two-dimensional material layer 1. Hereinafter, differences between electromagnetic wave detector 126 and electromagnetic wave detector 100 will be mainly described.

As illustrated in FIG. 45, void 9 is formed, for example, between two-dimensional material layer 1 and insulating film 3. Two-dimensional material layer 1 has a surface facing void 9. Two-dimensional material layer 1 is not in contact with insulating film 3. For example, a lower surface of third portion 1c of two-dimensional material layer 1 faces void 9.

First portion 1a of two-dimensional material layer 1 is electrically connected to semiconductor layer 4 via connection conductor portion 2d. Connection conductor portion 2d may have a similar configuration to that of connection conductor portion 2d in the ninth embodiment.

Preferably, the upper surface of connection conductor portion 2d is at the same height as the upper surface of first electrode portion 2a. The two-dimensional surfaces of first portion 1a, second portion 1b, and third portion 1c of two-dimensional material layer 1 extend in the same direction.

Void 9 is formed between first electrode portion 2a and connection conductor portion 2d.

Note that, in electromagnetic wave detector 126, a relative positional relationship between void 9 and first electrode portion 2a or connection conductor portion 2d is not particularly limited as long as void 9 is formed between two-dimensional material layer 1 and insulating film 3.

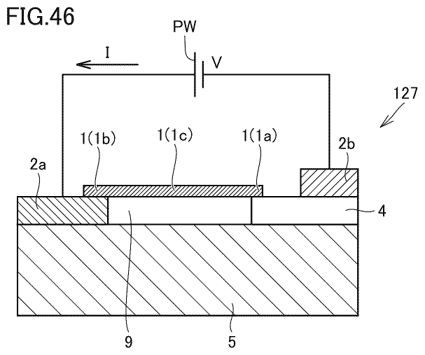

FIG. 46 is a schematic cross-sectional view illustrating a variation of the electromagnetic wave detector according to the twenty-first embodiment. An electromagnetic wave detector 127 illustrated in FIG. 46 basically has a similar configuration to that of electromagnetic wave detector 126 illustrated in FIG. 45 and can obtain similar effects, but is different from electromagnetic wave detector 126 in that void 9 is formed between two-dimensional material layer 1 and thermoelectric conversion material layer 5.

As illustrated in FIG. 46, two-dimensional material layer 1 is not in contact with thermoelectric conversion material layer 5. In electromagnetic wave detector 127, the potential difference generated in thermoelectric conversion material layer 5 by irradiating thermoelectric conversion material layer 5 with the electromagnetic wave causes the change in the electric field in two-dimensional material layer 1 via first electrode portion 2a or semiconductor layer 4. In other words, the optical gate effect can also be exhibited in electromagnetic wave detector 127. At this time, the direction of the above potential difference of thermoelectric conversion material layer 5 may be parallel to the two-dimensional surface of two-dimensional material layer 1.

Further, in electromagnetic wave detector 127, the potential difference generated in thermoelectric conversion material layer 5 by irradiating thermoelectric conversion material layer 5 with the electromagnetic wave may cause the change in the electric field in two-dimensional material layer 1 via void 9. The direction of the above potential difference of thermoelectric conversion material layer 5 may be orthogonal to the two-dimensional surface of two-dimensional material layer 1.

Preferably, the upper surface of semiconductor layer 4 is at the same height as the upper surface of first electrode portion 2a. The two-dimensional surfaces of first portion 1a, second portion 1b, and third portion 1c of two-dimensional material layer 1 extend in the same direction.

Void 9 is formed between first electrode portion 2a and semiconductor layer 4.

Note that in electromagnetic wave detector 127, a relative positional relationship between void 9 and first electrode portion 2a or semiconductor layer 4 is not particularly limited as long as void 9 is formed between two-dimensional material layer 1 and thermoelectric conversion material layer 5.

Here, the configuration of the electromagnetic wave detector according to the present embodiment can also be applied to other embodiments.

### <Operation and Effect>

In electromagnetic wave detector 126 and electromagnetic wave detector 127, void 9 is formed between two-dimensional material layer 1 and insulating film 3 or between two-dimensional material layer 1 and semiconductor layer 4. In this case, the influence of the carrier scattering on a contact surface between two-dimensional material layer 1 and insulating film 3 or a contact surface between two-dimensional material layer 1 and thermoelectric conversion material layer 5 can be suppressed. As a result, detection sensitivity of electromagnetic wave detectors 126 and 127 is improved.

Note that a thickness of void 9 is not particularly limited as long as the influence of the carrier scattering can be suppressed. However, from a viewpoint of enhancing the optical gate effect, a width of void 9 is preferably as thin as possible.

### Twenty-Second Embodiment

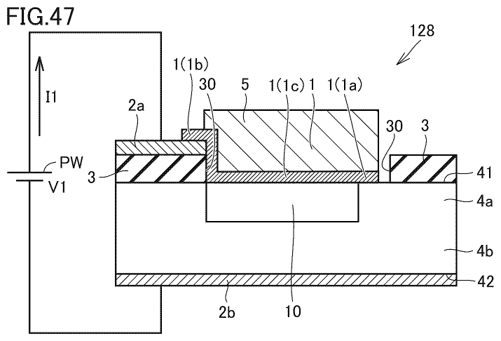

FIG. 47 is a schematic cross-sectional view of the electromagnetic wave detector according to the twenty-second embodiment. An electromagnetic wave detector 128 illustrated in FIG. 47 basically has a similar configuration to that of electromagnetic wave detector 100 illustrated in FIGS. 1 and 2, and can obtain similar effects, but is different from electromagnetic wave detector 100 in that an engraved structure 10 is formed around two-dimensional material layer 1.

An inner portion of engraved structure 10 is, for example, a void. Accordingly, electromagnetic wave detector 128 has a similar configuration to that of electromagnetic wave detector 127 in that void 9 is formed around two-dimensional material layer 1, but is different from electromagnetic wave detector 127 in that void 9 is formed by engraved structure 10 formed in a member disposed around two-dimensional material layer 1.

Hereinafter, differences of electromagnetic wave detector 128 from electromagnetic wave detector 100 and electromagnetic wave detector 127 will be mainly described.

As illustrated in FIG. 47, engraved structure 10 is formed in semiconductor layer 4 located in openings 30 of insulating film 3, for example, Engraved structure 10 includes a recess recessed with respect to first surface 41 of semiconductor layer 4. Two-dimensional material layer 1 has a surface facing engraved structure 10. For example, the lower surface of third portion 1c of two-dimensional material layer 1 faces engraved structure 10.

Engraved structure 10 is formed between first electrode portion 2a and semiconductor layer 4. A side surface of engraved structure 10 is formed to be flush with, for example, the inner peripheral surfaces of openings 30 of insulating film 3 and the end surface of first electrode portion 2a.

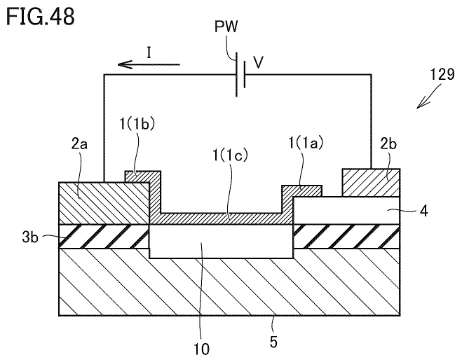

FIG. 48 is a schematic cross-sectional view illustrating a variation of the electromagnetic wave detector according to the twenty-second embodiment. An electromagnetic wave detector 129 illustrated in FIG. 48 basically has a similar configuration to that of electromagnetic wave detector 128 illustrated in FIG. 47 and can obtain similar effects, but is different from electromagnetic wave detector 128 in that engraved structure 10 is formed in insulating film 3 and thermoelectric conversion material layer 5. From a different a viewpoint, in electromagnetic wave detector 129, engraved structure 10 is configured by a combination of opening 30 formed in insulating film 3 and the recess formed in thermoelectric conversion material layer 5 to overlap with opening 30 in plan view.

As illustrated in FIG. 48, two-dimensional material layer 1 is not in contact with thermoelectric conversion material layer 5. In electromagnetic wave detector 129, the potential difference generated in thermoelectric conversion material layer 5 by irradiating thermoelectric conversion material layer 5 with the electromagnetic wave causes the change in the electric field in two-dimensional material layer 1 via first electrode portion 2a or semiconductor layer 4. In other words, the optical gate effect can also be exhibited in electromagnetic wave detector 129. At this time, the direction of the above potential difference of thermoelectric conversion material layer 5 may be parallel to the two-dimensional surface of two-dimensional material layer 1.

Further, in electromagnetic wave detector 129, the potential difference generated in thermoelectric conversion material layer 5 by irradiating thermoelectric conversion material layer 5 with the electromagnetic wave may cause the change in the electric field in two-dimensional material layer 1 via engraved structure 10. The direction of the above potential difference of thermoelectric conversion material layer 5 may be orthogonal to the two-dimensional surface of two-dimensional material layer 1. The two-dimensional surfaces of first portion 1a, second portion 1b, and third portion 1c of two-dimensional material layer 1 extend in the same direction.

Here, the configuration of the electromagnetic wave detector according to the present embodiment can also be applied to other embodiments.

### <Operation and Effect>

In electromagnetic wave detector 128, engraved structure 10 is formed in insulating film 3 and semiconductor layer 4. In this case, the influence of the carrier scattering on a contact surface between two-dimensional material layer 1 and semiconductor layer 4 can be suppressed. Further, in electromagnetic wave detector 129, engraved structure 10 is formed in insulating film 3 and thermoelectric conversion material layer 5. In this case, the influence of the carrier scattering on the contact surface between two-dimensional material layer 1 and thermoelectric conversion material layer 5 can be suppressed. As a result, detection sensitivity is improved in electromagnetic wave detectors 128 and 129.

In electromagnetic wave detectors 128 and 129, engraved structure 10 can be formed, for example, by partially etching semiconductor layer 4 exposed in opening 30 after opening 30 is formed in insulating film 3 formed on semiconductor layer 4.

Note that, in electromagnetic wave detectors 128 and 129, a thickness of engraved structure 10 is not particularly limited as long as the influence of the carrier scattering can be suppressed. However, from the viewpoint of enhancing the optical gate effect, a width of engraved structure 10 is preferably as thin as possible.

Further, in electromagnetic wave detectors 128 and 129, a relative positional relationship between engraved structure 10 and first electrode portion 2a or semiconductor layer 4 is not particularly limited.

### Twenty-Third Embodiment

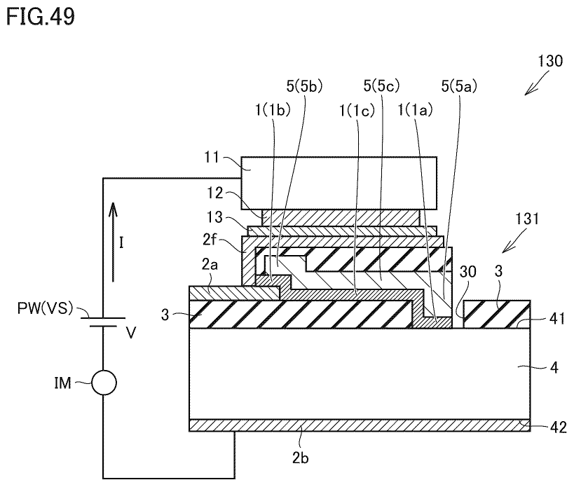

FIG. 49 is a schematic cross-sectional view of the electromagnetic wave detector according to the twenty-third embodiment. An electromagnetic wave detector 130 illustrated in FIG. 49 basically has a similar configuration to that of electromagnetic wave detector 100 illustrated in FIGS. 1 and 2 and can obtain similar effects, but is different from electromagnetic wave detector 100 in that electromagnetic wave detector 130 includes a readout circuit 11 configured to read out a signal from a main body 131 of the electromagnetic wave detector having a configuration equivalent to electromagnetic wave detector 100. Note that main body 131 of electromagnetic wave detector may have a configuration equivalent to any of electromagnetic wave detectors 100 to 129. Hereinafter, differences between electromagnetic wave detector 130 and electromagnetic wave detector 100 will be mainly described.

As illustrated in FIG. 49, main body 131 of the electromagnetic wave detector is disposed on readout circuit 11. A readout format of readout circuit 11 is, for example, a capacitive transimpedance amplifier (CTIA) type. Readout circuit 11 may have another readout format. Readout circuit 11 is formed on a silicon substrate.

Main body 131 of the electromagnetic wave detector further includes, for example, a control electrode 2f electrically connected to first electrode portion 2a. Control electrode 2f includes, for example, a portion formed on insulating film 3.

Electromagnetic wave detector 130 further includes a bump 12 and a pad 13 for electrically connecting control electrode 2f of main body 131 of the electromagnetic wave detector and readout circuit 11. Pad 13 is electrically connected to control electrode 2f. Pad 13 is formed on control electrode 2f, for example. Bump 12 electrically connects pad 13 and readout circuit 11. Bump 12 is formed on pad 13.

A structure in which main body 131 of the electromagnetic wave detector and readout circuit 11 are connected by bump 12 is called hybrid junction. Hybrid junction is a general structure in a quantum type infrared sensor.

A material constituting bump 12 may be any conductive material, and includes indium (In), for example. A material constituting pad 13 may be any conductive material, and includes, for example, at least one selected from the group consisting of an aluminum silicon (Al—Si)-based alloy, nickel (Ni), and gold (Au).

In electromagnetic wave detector 130, any semiconductor material other than the silicon can be adopted as the material constituting semiconductor layer 4 of main body 131 of the electromagnetic wave detector. For example, as the material constituting semiconductor layer 4, the material such as the compound semiconductor, for example, germanium (Ge), the group III-V or group II-V semiconductor; the substrate containing mercury cadmium tellurium (HgCdTe), indium antimony (InSb), lead selenium (PbSe), lead sulfur (PbS), cadmium sulfur (CdS), gallium nitride (GaN), silicon carbide (SiC), gallium phosphide (GaP), indium gallium arsenide (InGaAs), indium arsenide (InAs), the quantum well or the quantum dot; or the Type II superlattice may be used alone, or in combination with each other.

### <Operation and Effect>

Electromagnetic wave detector 130 includes readout circuit 11 configured to read out the signal from main body 131 of the electromagnetic wave detector. In general, a silicon substrate is used for manufacturing the readout circuit in the electromagnetic wave detector. Therefore, in a case where the silicon is used for semiconductor layer 4, the readout circuit can be formed on the same substrate. However, in a case where, for semiconductor layer 4, the material such as a semiconductor other than the silicon, for example, the compound semiconductor such as germanium (Ge), the group III-V or group II-V semiconductor; the substrate containing mercury cadmium tellurium (HgCdTe), indium antimony (InSb), lead selenium (PbSe), lead sulfur (PbS), cadmium sulfur (CdS), gallium nitride (GaN), silicon carbide (SiC), gallium phosphide (GaP), indium gallium arsenide (InGaAs), indium arsenide (InAs), the quantum well or the quantum dot; or the Type II superlattice is used alone, or in combination with each other, it is difficult to form the readout circuits on the semiconductor layer made of these materials.

In electromagnetic wave detector 130, even in a case where the semiconductor other than the silicon described above is used for semiconductor layer 4, it is easy to join readout circuit 11 formed on the silicon substrate onto semiconductor layer 4. Therefore, electromagnetic wave detector 130 can be relatively easily manufactured regardless of the semiconductor material constituting semiconductor layer 4.

### Twenty-Fourth Embodiment

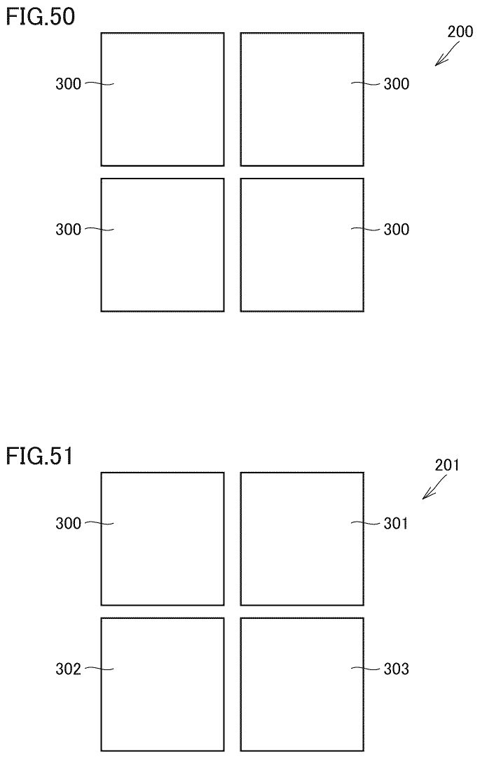

FIG. 50 is a schematic plan view of the electromagnetic wave detector array according to the twenty-fourth embodiment. FIG. 51 is a plan view illustrating a variation of the electromagnetic wave detector according to the twenty-fourth embodiment.

An electromagnetic wave detector array 200 illustrated in FIG. 50 is an electromagnetic wave detector assembly, and includes a plurality of electromagnetic wave detectors 300 as detection elements. Each of the plurality of electromagnetic wave detectors 300 is any one of electromagnetic wave detectors 100 to 130 of the first embodiment to the twenty-third embodiment. For example, each of electromagnetic wave detectors 300 may be electromagnetic wave detector 100. In electromagnetic wave detector array 200 illustrated in FIG. 50, each of the plurality of electromagnetic wave detectors 3W) is disposed in an array in a two-dimensional direction. Note that each of the plurality of electromagnetic wave detectors 300 may be disposed in line in a one-dimensional direction. In a case where each of the plurality of electromagnetic wave detectors 300 is electromagnetic wave detector 130, each of the plurality of electromagnetic wave detectors 300 may include a substrate on which readout circuit 11 is formed, or readout circuit i 1 of each of the plurality of electromagnetic wave detectors 300 may be integrated on one substrate.

As illustrated in FIG. 50, electromagnetic wave detector array 200 includes four electromagnetic wave detectors 300, and the four electromagnetic wave detectors 300 are disposed in a two-by-two array. However, electromagnetic wave detector array 200 may include any number of electromagnetic wave detectors 300, and may include, for example, nine or more electromagnetic wave detectors 300. The plurality of electromagnetic wave detectors 100 may be disposed in an array of three or more electromagnetic wave detectors by three or more electromagnetic wave detectors.

Further, in electromagnetic wave detector array 200, the plurality of electromagnetic wave detectors 300 may be disposed aperiodically.

Further, in electromagnetic wave detector array 200, a constituent member of each of electromagnetic wave detectors 300 may be shared as long as each of the plurality of electromagnetic wave detectors 300 can function as one detection element. For example, second electrode portion 2b of each of electromagnetic wave detectors 300 may be a common electrode. If second electrode portion 2b is the common electrode, the number of wirings between the detection elements can be reduced as compared with a configuration in which second electrode portions 2b of electromagnetic wave detectors 300 are independent from each other. As a result, a resolution of electromagnetic wave detector array 200 can be increased.

Each of the plurality of electromagnetic wave detectors 300 forms one pixel in electromagnetic wave detector array 200, for example. In this case, electromagnetic wave detector array 200 can be used as, for example, an image sensor having each of the plurality of electromagnetic wave detectors 300 as one pixel.

Each of the plurality of electromagnetic wave detectors 300 may be an electromagnetic wave detector according to another embodiment other than electromagnetic wave detector 100 according to the first embodiment.

An electromagnetic wave detector array 201 illustrated in FIG. 51 basically has a similar configuration to that of electromagnetic wave detector array 200 illustrated in FIG. 50 and can obtain similar effects, but is different from electromagnetic wave detector array 200 in that electromagnetic wave detector array 201 includes a plurality of electromagnetic wave detectors 300, 301, 302, and 303 having configurations different from each other. Each of the plurality of electromagnetic wave detectors 300, 301, 302, and 303 is any one of electromagnetic wave detectors 100 to 130 of the first embodiment to the twenty-first embodiment. For example, electromagnetic wave detector 300 may be electromagnetic wave detector 100, electromagnetic wave detector 301 may be electromagnetic wave detector 101, electromagnetic wave detector 302 may be electromagnetic wave detector 102, and electromagnetic wave detector 303 may be electromagnetic wave detector 103.

In electromagnetic wave detector array 201 illustrated in FIG. 51, since the plurality of electromagnetic wave detectors 300, 301, 302, and 303 of different types from each other is disposed in a one-dimensional or two-dimensional array, a function as an image sensor can be provided. For example, electromagnetic wave detectors having different detection wavelengths may be used as electromagnetic wave detectors 300, 301, 302, and 303. Specifically, electromagnetic wave detectors having detection wavelength selectivity different from the electromagnetic wave detector according to any one of the first embodiment to the twenty-first embodiment are prepared, and may be arranged in an array. In this case, electromagnetic wave detector array 201 can detect at least two or more electromagnetic waves, which have different wavelengths.

By disposing electromagnetic wave detectors 300, 301, 302, and 303 having the different detection wavelengths in the array in this manner, the wavelengths of the electromagnetic waves can be identified in any wavelength region such as a wavelength region of ultraviolet light, infrared light, a terahertz wave, or a radio wave, similarly to an image sensor used in a visible light region. As a result, for example, a colored image in which differences in the wavelengths are indicated as differences in colors can be obtained.

The material constituting semiconductor layer 4 of each of the plurality of electromagnetic wave detectors 300, 301, 302, and 303 of different types may be a material having a different detection wavelength. For example, the material constituting semiconductor layer 4 of electromagnetic wave detector 300 may be a semiconductor material having a detection wavelength being a wavelength of the visible light, and the material constituting semiconductor layer 4 of electromagnetic wave detector 301 may be a semiconductor material having a detection wavelength being a wavelength of the infrared light. Such electromagnetic wave detector array 201 is suitable for, for example, an in-vehicle sensor. Such electromagnetic wave detector array 201 can function as an image sensor for a visible light image camera in the daytime and as an image sensor for an infrared camera at night. Accordingly, according to the camera including electromagnetic wave detector array 201 as the image sensor as described above, it is not necessary to selectively use the cameras according to the detection wavelength.

Electromagnetic wave detector array 201 including the plurality of electromagnetic wave detectors 300, 301, 302, and 303 having the detection wavelengths different from each other can be used as an image sensor that can detect a plurality of the electromagnetic waves having the wavelengths different from each other. Accordingly, it is possible to detect the plurality of the electromagnetic waves having the wavelengths different from each other without using a color filter conventionally required for a complementary MOS (CMOS) sensor or the like. Further, it is possible to obtain a colored image in which differences in the wavelengths of the electromagnetic waves are indicated as differences in colors.

Moreover, a polarization identification image sensor can be formed by arraying electromagnetic wave detectors 300, 301, 302, and 303 having different polarizations to be detected. For example, polarization imaging can be performed by disposing the plurality of the electromagnetic wave detectors in one unit of four pixels having detected polarization angles of 0°, 90°, 45°, and 135°. The polarization identification image sensor enables, for example, identification of an artifact and a natural object, material identification, identification of an object having the same temperature in an infrared wavelength range, identification of a boundary between objects, or improvement of equivalent resolution.

Also in electromagnetic wave detector array 201 illustrated in FIG. 51, arrangement of the plurality of electromagnetic wave detectors 300, 301, 302, and 303 is not particularly limited. The plurality of electromagnetic wave detectors 300, 301, 302, and 303 may be arranged periodically or aperiodically.

As described above, the electromagnetic wave detector assembly according to the present embodiment configured as described above can detect an electromagnetic wave in a wide wavelength range. Further, the electromagnetic wave detector assembly according to the present embodiment can detect the electromagnetic waves of the different wavelengths.

Note that, in each of the embodiments described above, at least one of the material constituting insulating film 3, the material constituting semiconductor layer 4, and the material constituting contact layers 8 may contain a material that has characteristics changed by the irradiation with the electromagnetic wave and gives a change in potential to two-dimensional material layer 1. Examples of the material that has the characteristics changed by the irradiation with the electromagnetic wave and gives the change in the potential to two-dimensional material layer 1 include the thermoelectric conversion material, a quantum dot, a ferroelectric material, a liquid crystal material, fullerene, a rare earth oxide, a semiconductor material, a pn junction material, a metal-semiconductor junction material, or a metal-insulator-semiconductor junction material.

For example, at least one of the material constituting insulating film 3, the material constituting semiconductor layer 4, and the material constituting contact layers 8 may contain the thermoelectric conversion material. In this case, when insulating film 3, semiconductor layer 4, or contact layers 8 is irradiated with the electromagnetic wave, a thermoelectric power generation effect similar to that of thermoelectric conversion material layer 5 also occurs in insulating film 3, semiconductor layer 4, or contact layers 8, and as a result, the change in the potential can be given to two-dimensional material layer 1 due to the thermoelectric power generation effect exhibited in these members.

Note that, for example, in a case where the material constituting contact layers 8 contains the thermoelectric conversion material, such contact layers 8 may not be in contact with two-dimensional material layer 1. Such contact layers 8 may be disposed on the upper surface or the lower surface of two-dimensional material layer 1 via the insulating film or the like as long as the change in the potential is given to two-dimensional material layer 1 due to the thermoelectric power generation effect.

Further, the electromagnetic wave detector according to each of the embodiments described above may further include the thermoelectric conversion material layer in contact with second electrode portion 2b. Further, the electromagnetic wave detector according to the present disclosure may include only the thermoelectric conversion material layer in contact with second electrode portion 2b as the thermoelectric conversion material layer. In this case, the thermoelectric conversion material layer may be arranged to change the potential difference between first electrode portion 2a and second electrode portion 2b when the potential difference of the thermoelectric conversion material layer changes due to the thermoelectric power generation effect.

The embodiments described above can be appropriately varied or omitted. Moreover, the above embodiments can be variously varied without departing from the gist thereof in implementation stages. Further, the above embodiments include inventions at various stages, and various inventions can be extracted by appropriately combining a plurality of disclosed constituent elements.

### REFERENCE SIGNS LIST

1: two-dimensional material layer, 1a: first portion, 1b: second portion, 1c: third portion, 2a: first electrode portion, 2b: second electrode portion, 2c: third electrode portion, 2d: connection conductor portion, 2e: fourth electrode portion. 3, 3b: insulating film, 4, 4a, 4b: semiconductor layer, 5: thermoelectric conversion material layer, 5a: fourth portion, 5b: fifth portion, 5c: sixth portion, 5d: first thermoelectric conversion material portion, 5e: second thermoelectric conversion material portion, 5f: third thermoelectric conversion material portion, 5g: fourth thermoelectric conversion material portion, 5h: first conductive portion, 5i: second conductive portion, 5j: fifth thermoelectric conversion material portion, 5k: third conductive portion, 6: tunnel insulating layer, 7: conductor, 8: contact layer, 9: void, 10: engraved structure, 30: opening, 41: first surface, 42: second surface, 51: third surface, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 300, 301, 302, 303: electromagnetic wave detector, 200, 201: electromagnetic wave detector array.

1. An electromagnetic wave detector comprising:
a semiconductor layer having a first surface;
a two-dimensional material layer electrically connected to the semiconductor layer;
a first electrode portion electrically connected to the two-dimensional material layer without the semiconductor layer between the first electrode portion and the two-dimensional material layer;
a second electrode portion electrically connected to the two-dimensional material layer via the semiconductor layer; and
a thermoelectric conversion material layer, wherein
the thermoelectric conversion material layer is in contact with the two-dimensional material layer, or spaced apart from the two-dimensional material layer and arranged to change a potential difference between the first electrode portion and the second electrode portion when a potential difference in the thermoelectric conversion material layer changes,
the thermoelectric conversion material layer is arranged to change an electric resistance value of the two-dimensional material layer when a potential difference generated in the thermoelectric conversion material layer changes,
the two-dimensional material layer includes a first portion in contact with the semiconductor layer or a conductive member electrically connected to the semiconductor layer, and
the thermoelectric conversion material layer is in contact with at least the first portion of the two-dimensional material layer, or the thermoelectric conversion material layer is spaced apart from the two-dimensional material layer and disposed to overlap with only the first electrode portion of the two-dimensional material layer and the first electrode portion.

2.-3. (canceled)

4. The electromagnetic wave detector according to claim 1, wherein
the two-dimensional material layer includes the first portion in contact with the semiconductor layer or the conductive member electrically connected to the semiconductor layer, a second portion in contact with the first electrode portion, and a third portion electrically connecting the first portion and the second portion, and
the thermoelectric conversion material layer is in contact with at least the third portion of the two-dimensional material layer.

5. The electromagnetic wave detector according to claim 4, wherein the thermoelectric conversion material layer is in contact with each of the first portion, the second portion, and the third portion of the two-dimensional material layer.

6. An electromagnetic wave detector comprising:
a semiconductor layer having a first surface;
a two-dimensional material layer electrically connected to the semiconductor layer;
a first electrode portion electrically connected to the two-dimensional material layer without the semiconductor layer between the first electrode portion and the two-dimensional material layer;
a second electrode portion electrically connected to the two-dimensional material laver via the semiconductor layer; and
a thermoelectric conversion material layer, wherein
the thermoelectric conversion material layer is in contact with the two-dimensional material layer, or spaced apart from the two-dimensional material layer and arranged to change a potential difference between the first electrode portion and the second electrode portion when a potential difference in the thermoelectric conversion material layer changes,
the thermoelectric conversion material layer is arranged to change an electric resistance value of the two-dimensional material layer when a potential difference generated in the thermoelectric conversion material layer changes,
the two-dimensional material layer includes a first portion in contact with the semiconductor layer or a conductive member electrically connected to the semiconductor layer, a second portion in contact with the first electrode portion, and a third portion electrically connecting the first portion and the second portion,
the electromagnetic wave detector further comprising an insulating film to separate at least one of the first portion, the second portion, and the third portion of the two-dimensional material layer from the thermoelectric conversion material layer,
each of the first portion, the second portion, and the third portion of the two-dimensional material layer being spaced apart from the thermoelectric conversion material layer.

7. An electromagnetic wave detector comprising:
a semiconductor layer having a first surface;
a two-dimensional material layer electrically connected to the semiconductor layer;
a first electrode portion electrically connected to the two-dimensional material laver without the semiconductor layer between the first electrode portion and the two-dimensional material layer;
a second electrode portion electrically connected to the two-dimensional material laver via the semiconductor layer; and
a thermoelectric conversion material layer, wherein
the thermoelectric conversion material layer is in contact with the two-dimensional material layer, or spaced apart from the two-dimensional material layer and arranged to change a potential difference between the first electrode portion and the second electrode portion when a potential difference in the thermoelectric conversion material layer changes,
the thermoelectric conversion material layer is arranged to change an electric resistance value of the two-dimensional material layer when a potential difference generated in the thermoelectric conversion material layer changes,
the two-dimensional material layer includes a first portion in contact with the semiconductor layer or a conductive member electrically connected to the semiconductor layer, a second portion in contact with the first electrode portion, and a third portion electrically connecting the first portion and the second portion,
the thermoelectric conversion material layer is in contact with only the second portion of the two-dimensional material layer, and
the thermoelectric conversion material layer is configured as a same member as the first electrode portion.

8. The electromagnetic wave detector according to claim 1, wherein the first portion or the conductive member is in a Schottky junction with the semiconductor layer.

9. The electromagnetic wave detector according to claim 1, wherein the first electrode portion is formed in an annular shape in plan view, and the first portion is disposed on an inner side than the first electrode portion.

10. The electromagnetic wave detector according to claim 8, wherein the first portion has an end portion of the two-dimensional material layer in plan view.

11. The electromagnetic wave detector according to claim 1, further comprising a tunnel insulating layer disposed between the two-dimensional material layer and the semiconductor layer, wherein
a thickness of the tunnel insulating layer is set to generate a tunnel current between the two-dimensional material layer and the semiconductor layer when an electromagnetic wave to be detected is incident on the two-dimensional material layer and the thermoelectric conversion material layer.

12. (canceled)

13. The electromagnetic wave detector according to claim 1, wherein the thermoelectric conversion material layer is disposed on a side opposite to the semiconductor layer with respect to the two-dimensional material layer.

14. The electromagnetic wave detector according to claim 1, wherein the thermoelectric conversion material layer is disposed closer to the semiconductor layer than the two-dimensional material layer, and
the semiconductor layer, the two-dimensional material layer, the first electrode portion, and the second electrode portion are disposed on the thermoelectric conversion material layer.

15.-16. (canceled)

17. The electromagnetic wave detector according to claim 1, further comprising a third electrode portion in contact with the thermoelectric conversion material layer.

18. The electromagnetic wave detector according to claim 1, wherein the thermoelectric conversion material layer is arranged to generate an electric field in a direction perpendicular to an extending direction of the two-dimensional material layer when an electromagnetic wave to be detected is incident on the thermoelectric conversion material layer,
the two-dimensional material layer includes a region in contact with the semiconductor layer, and
the thermoelectric conversion material layer is arranged to generate the electric field in the direction perpendicular to the extending direction of the two-dimensional material layer in a region of the two-dimensional material layer in contact with the semiconductor layer.

19. (canceled)

20. The electromagnetic wave detector according to claim 1, wherein the thermoelectric conversion material layer includes a first thermoelectric conversion material portion containing a first thermoelectric conversion material, and a second thermoelectric conversion material portion containing a second thermoelectric conversion material different from the first thermoelectric conversion material.

21. The electromagnetic wave detector according to claim 20, wherein an electromagnetic wave absorption wavelength of the first thermoelectric conversion material is different from an electromagnetic wave absorption wavelength of the second thermoelectric conversion material, or a Seebeck coefficient of the first thermoelectric conversion material is different from a Seebeck coefficient of the second thermoelectric conversion material.

22. The electromagnetic wave detector according to claim 1, wherein the thermoelectric conversion material layer includes a π-type structure portion in which a plurality of thermoelectric conversion material portions having polarities different from each other are connected in series via an electrode.

23.-24. (canceled)

25. The electromagnetic wave detector according to claim 1, wherein
the semiconductor layer includes a first semiconductor portion of a first conductive type and a second semiconductor portion of a second conductive type,
the two-dimensional material layer is electrically connected to the first semiconductor portion, and
the second electrode portion is electrically connected to the two-dimensional material layer via the second semiconductor portion.

26. The electromagnetic wave detector according to claim 25, wherein the two-dimensional material layer is electrically connected to the first semiconductor portion and the second semiconductor portion,
the electromagnetic wave detector further comprising a fourth electrode portion electrically connected to the first semiconductor portion.

27.-37. (canceled)
